(19) United States
(12) Patent Application Publication
(10) Pub. No.: US 2025/0275187 A1
(43) Pub. Date: Aug. 28, 2025

(54) SEMICONDUCTOR DEVICE

(71) Applicant: Japan Display Inc., Tokyo (JP)

(72) Inventors: Akihiro HANADA, Tokyo (JP); Takuo KAITOH, Tokyo (JP); Motochika YUKAWA, Tokyo (JP)

(73) Assignee: Japan Display Inc., Tokyo (JP)

(21) Appl. No.: 19/052,357

(22) Filed: Feb. 13, 2025

(30) Foreign Application Priority Data
Feb. 22, 2024 (JP) 2024-025221

(51) Int. Cl. H10D 30/67; H10D 30/01; H10D 62/10; H10D 62/60

(52) U.S. Cl. CPC H10D 30/6756; H10D 30/6723; H10D 30/6729; H10D 30/6731; H10D 30/6736; H10D 62/115; H10D 62/60; H10D 30/0314

(57) ABSTRACT

A semiconductor device according to an embodiment of the present invention includes: a first oxide insulating layer; an oxide semiconductor layer above the first oxide insulating layer; a second oxide insulating layer covering the oxide semiconductor layer; a nitride insulating layer above the second oxide insulating layer; a gate electrode above the nitride insulating layer; and an insulating layer covering the gate electrode, wherein the nitride insulating layer has a first sidewall having a shape matching a pattern of the gate electrode in a plan view, and the first sidewall is in contact with the insulating layer.

### CROSS REFERENCE TO RELATED APPLICATIONS

This application claims the benefit of priority to Japanese Patent Application No. 2024-025221 filed on Feb. 22, 2024, the entire contents of which are incorporated herein by reference.

### FIELD

An embodiment of the present invention relates to a semiconductor device using an oxide semiconductor for a channel.

### BACKGROUND

In recent years, a semiconductor device in which an oxide semiconductor is used for a channel instead of silicon semiconductors such as amorphous silicon, low-temperature polysilicon, and single-crystal silicon has been developed (for example, Japanese laid-open patent publication No. 2021-141338). The semiconductor device including such an oxide semiconductor can be formed with a simple structure and a low-temperature process, similar to a thin film transistor including amorphous silicon. The semiconductor device including the oxide semiconductor is known to have higher field-effect mobility than the semiconductor device including amorphous silicon.

In the oxide semiconductor, carriers are generated when hydrogen bonds to oxygen defects. In the semiconductor device, this mechanism can be used to form a source region and a drain region, which are low-resistance regions, by forming oxygen defects in an oxide semiconductor layer and supplying hydrogen to the oxygen defects. On the other hand, when hydrogen diffuses into a channel region of the oxide semiconductor layer, the characteristics of the semiconductor device as a channel deteriorate. Specifically, the diffusion of hydrogen into the channel region CH changes the threshold voltage in the electrical characteristics of the semiconductor device, so that the variation in the threshold voltage increases and the manufacturing yield of the semiconductor device decreases. Therefore, using an oxide layer containing excessive oxygen capable of trapping hydrogen as an insulating layer in contact with the oxide semiconductor layer makes it possible to suppress hydrogen from entering the channel region.

However, since the oxide layer containing excessive oxygen functions as an electron-trap, the reliability of the semiconductor device containing such an oxide layer is significantly reduced. Therefore, in order to suppress a decrease in reliability there is a demand for a semiconductor device capable of supplying hydrogen to the source region and the drain region of the oxide semiconductor layer and suppressing hydrogen from entering the channel region of the oxide semiconductor layer.

### SUMMARY

A semiconductor device according to an embodiment of the present invention includes: a first oxide insulating layer; an oxide semiconductor layer above the first oxide insulating layer; a second oxide insulating layer covering the oxide semiconductor layer; a nitride insulating layer above the second oxide insulating layer; a gate electrode above the nitride insulating layer; and an insulating layer covering the gate electrode, wherein the nitride insulating layer has a first sidewall having a shape matching a pattern of the gate electrode in a plan view, and the first sidewall is in contact with the insulating layer.

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a schematic partially enlarged cross-sectional view showing a configuration of a semiconductor device according to an embodiment of the present invention.

FIG. 4 is a graph showing profiles of an impurity concentrations in a first region to a third region in a semiconductor device according to the embodiment of the present invention.

FIG. 5 is a sequence diagram showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a schematic cross-sectional view illustrating a hydrogen-trapping function in the second region and the third region in a semiconductor device according to an embodiment of the present invention.

FIG. 15 is a schematic cross-sectional view illustrating a hydrogen-trapping function in the second region and the third region in a semiconductor device according to an embodiment of the present invention.

FIG. 16 is a schematic cross-sectional view illustrating effects of hydrogen-trapping and a diagram showing electrical characteristics of a semiconductor device according to an embodiment of the present invention.

FIG. 17 is a cross-sectional view showing an outline of a semiconductor device according to an embodiment of the present invention.

FIG. 18 is a schematic partially enlarged cross-sectional view showing a configuration of a semiconductor device according to an embodiment of the present invention.

FIG. 19 is a graph showing the profile of impurity concentrations in a first region to a third region in a semiconductor device according to the embodiment of the present invention.

FIG. 20 is a sequence diagram showing a method for manufacturing a semiconductor device according to an embodiment of the present invention.

FIG. 21 is a cross-sectional view showing a method for manufacturing a semiconductor device according to an embodiment of the present invention.

FIG. 22 is a cross-sectional view showing a method for manufacturing a semiconductor device according to an embodiment of the present invention.

FIG. 23 is a cross-sectional view showing an outline of a semiconductor device according to an embodiment of the present invention.

FIG. 24 is a schematic cross-sectional view illustrating a function of trapping hydrogen in a second region and a third region in a semiconductor device according to an embodiment of the present invention.

FIG. 25 is a graph showing the profile of an impurity concentration in the first region to the third region in a semiconductor device according to the embodiment of the present invention.

FIG. 26 is a sequence diagram showing a method for manufacturing a semiconductor device according to an embodiment of the present invention.

FIG. 27 is a cross-sectional view showing a method for manufacturing a semiconductor device according to an embodiment of the present invention.

FIG. 28 is a cross-sectional view showing a method for manufacturing a semiconductor device according to an embodiment of the present invention.

FIG. 29 is a cross-sectional view showing an outline of a semiconductor device according to an embodiment of the present invention.

FIG. 30 is a sequence diagram showing a method for manufacturing a semiconductor device according to an embodiment of the present invention.

FIG. 31 is a cross-sectional view showing an outline of a semiconductor device according to an embodiment of the present invention.

FIG. 32 is a cross-sectional view showing a method for manufacturing a semiconductor device according to an embodiment of the present invention.

FIG. 33 is a cross-sectional view showing a method for manufacturing a semiconductor device according to an embodiment of the present invention.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

In this specification, the terms “film” and “layer” can optionally be interchanged each other.

A “display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction.

The expressions “a includes A, B, or C”, “a includes any of A, B, and C”, and “a includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

In view of the above, an object of an embodiment of the present invention is to provide a semiconductor device including a hydrogen-trapping region that prevents hydrogen from entering a channel region.

### 1. First Embodiment

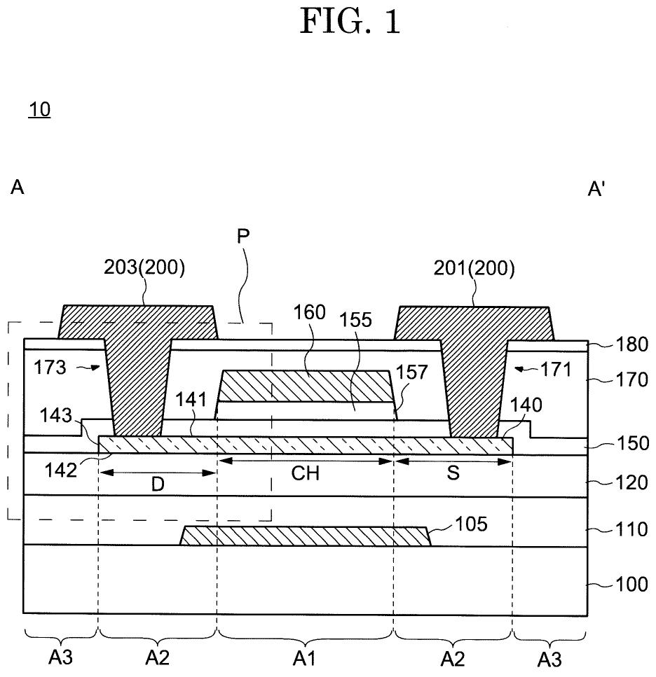

A semiconductor device according to an embodiment of the present invention will be described with reference to FIG. 1 to FIG. 16. For example, a semiconductor device of the embodiment described below may be used in an integrated circuit (IC) such as a micro-processing unit (MPU) or a memory circuit in addition to a transistor used in a display device.

### [1-1. Configuration of Semiconductor Device 10]

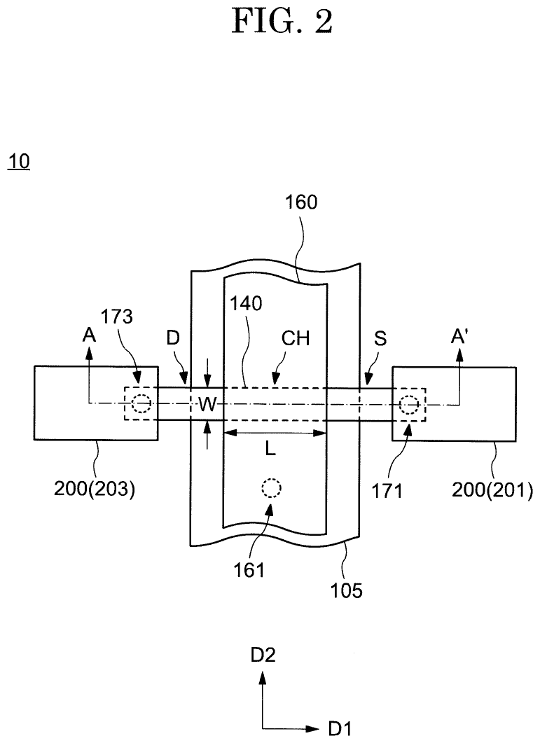

A configuration of a semiconductor device 10 according to an embodiment of the present invention will be described with reference to FIG. 1 and FIG. 2. FIG. 1 is a cross-sectional view showing an outline of a semiconductor device according to an embodiment of the present invention. FIG. 2 is a plan view showing an outline of a semiconductor device according to an embodiment of the present invention.

As shown in FIG. 1, the semiconductor device 10 is arranged above a substrate 100. The semiconductor device 10 includes a light-shielding layer 105, a nitride insulating layer 110 and an oxide insulating layer 120, a metal oxide layer 130, an oxide semiconductor layer 140, an oxide insulating layer 150, a nitride insulating layer 155, a gate electrode 160, insulating layers 170 and 180, a source electrode 201, and a drain electrode 203. If the source electrode 201 and the drain electrode 203 are not specifically distinguished from each other, they may be referred to as a source/drain electrode 200. The oxide insulating layer 120 is referred to as a “first oxide insulating layer.” The oxide insulating layer 150 is referred to as a “second oxide insulating layer.”

The light-shielding layer 105 is arranged on the substrate 100. The nitride insulating layer 110 and the oxide insulating layer 120 are arranged on the substrate 100 and the light-shielding layer 105. The nitride insulating layer 110 covers an upper surface and an end portion of the light-shielding layer 105. The oxide semiconductor layer 140 is arranged on the oxide insulating layer 120. The oxide semiconductor layer 140 is patterned. A part of the oxide insulating layer 120 extends outside the pattern of the oxide semiconductor layer 140 beyond end portions of the oxide semiconductor layer 140.

In the present embodiment, although a configuration in which the oxide insulating layer 120 and the oxide semiconductor layer 140 are in contact with each other is exemplified, the configuration is not limited to this configuration. For example, a metal oxide layer may be arranged between the oxide insulating layer 120 and the oxide semiconductor layer 140, and the oxide insulating layer 120 may not be in contact with the oxide insulating layer 150. For example, a metal oxide containing aluminum as the main component may be used as the metal oxide layer. Specifically, aluminum oxide may be used as the metal oxide layer.

The gate electrode 160 faces the oxide semiconductor layer 140 above the oxide semiconductor layer 140. The oxide insulating layer 150 and the nitride insulating layer 155 are arranged between the oxide semiconductor layer 140 and the gate electrode 160. The oxide insulating layer 150 and the nitride insulating layer 155 function as a gate insulating layer of the semiconductor device 10. In the following explanation, in the case where the oxide insulating layer 150 and the nitride insulating layer 155 do not need to be distinguished from each other, they may be collectively referred to as a “gate insulating layer”.

The nitride insulating layer 155 is arranged on the oxide insulating layer 150. The oxide insulating layer 150 covers an upper surface and an end portion of the oxide semiconductor layer 140. On the other hand, a pattern end of the nitride insulating layer 155 is substantially consistent with a pattern end of the gate electrode 160. That is, in a plan view, the pattern of the nitride insulating layer 155 is substantially consistent with the pattern of the gate electrode 160. In other words, a sidewall 157 of the nitride insulating layer 155 has a shape aligned with the pattern of the gate electrode 160 in a plan view. The sidewall 157 is in contact with the insulating layer 170. The sidewall 157 may be referred to as a “first sidewall.” The gate electrode 160 is arranged on the nitride insulating layer 155.

The oxide insulating layer 150 is in contact with the oxide semiconductor layer 140. A surface, which is in contact with the oxide insulating layer 150, among main surfaces of the oxide semiconductor layer 140 is an upper surface 141. A surface, which is in contact with the oxide insulating layer 120, among the main surfaces of the oxide semiconductor layer 140 is a lower surface 142. A surface between the upper surface 141 and the lower surface 142 is a side surface 143. The oxide insulating layer 150 covers the upper surface 141 and the side surface 143 of the oxide semiconductor layer 140 and is in contact with the oxide insulating layer 120 in a region (third region A3 described below) outside the pattern of the oxide semiconductor layer 140. In other words, the oxide insulating layer 150 covers the oxide semiconductor layer 140 and is arranged on the oxide insulating layer 120 and the oxide semiconductor layer 140.

The insulating layer 170 is arranged on the oxide insulating layer 150 and the gate electrode 160. The insulating layer 170 covers the gate electrode 160. The insulating layer 170 is in contact with the oxide insulating layer 150 in a region not overlapping the gate electrode 160 in a plan view. The insulating layer 180 is arranged on the insulating layer 170. Openings 171 and 173 that reach the oxide semiconductor layer 140 are arranged in the insulating layers 170 and 180 and the oxide insulating layer 150. The source electrode 201 is arranged inside the opening 171. The source electrode 201 is in contact with the oxide semiconductor layer 140 at the bottom of the opening 171. The drain electrode 203 is arranged inside the opening 173. The drain electrode 203 is in contact with the oxide semiconductor layer 140 at the bottom of the opening 173.

The light-shielding layer 105 has a function as a light-shielding film for the oxide semiconductor layer 140. The nitride insulating layer 110 functions as a barrier film that shields impurities that diffuse from the substrate 100 toward the oxide semiconductor layer 140. The light-shielding layer 105 may have a function as a bottom gate of the semiconductor device 10. In this case, the nitride insulating layer 110 and the oxide insulating layer 120 have a function as gate insulating layers for the bottom gate.

The operation of the semiconductor device 10 is controlled mainly by a voltage supplied to the gate electrode 160. In the case where the light-shielding layer 105 has a function as the bottom gate, an auxiliary voltage is supplied to the light-shielding layer 105. However, a voltage similar to the voltage supplied to the gate electrode 160 may be supplied to the light-shielding layer 105. On the other hand, in the case where the light-shielding layer 105 is simply used as a light-shielding film, a particular voltage is not supplied to the light-shielding layer 105, and the potential of the light-shielding layer 105 may be floating. Alternatively, the light-shielding layer 105 may be an insulator.

The semiconductor device 10 is divided into a first region A1, a second region A2, and a third region A3 based on the patterns of the gate electrode 160 and the oxide semiconductor layer 140. The first region A1 is a region that overlaps the gate electrode 160 in a plan view. The second region A2 is a region that does not overlap the gate electrode 160 but overlaps the oxide semiconductor layer 140 in a plan view. The third region A3 is a region that does not overlap both the gate electrode 160 and the oxide semiconductor layer 140 in a plan view.

The oxide insulating layer 150 is arranged in the first region A1, the second region A2, and the third region A3. On the other hand, the nitride insulating layer 155 is arranged only in the first region A1. The oxide insulating layer 150 and the nitride insulating layer 155 may be collectively referred to as a “gate insulating layer.” In this case, the above configuration can be expressed as follows. A thickness of the gate insulating layer in the second region A2 and the third region A3 is smaller than a thickness of the gate insulating layer in the first region A1. In other words, in a plan view, the thickness of the gate insulating layer in a region that does not overlap the gate electrode 160 is smaller than the thickness of the gate insulating layer in a region that overlaps the gate electrode 160.

The total thickness of the oxide insulating layer 150 and the nitride insulating layer 155 in the first region A1 is 200 nm or more. The total thickness of the oxide insulating layer 150 and the nitride insulating layer 155 in the first region A1 may be 250 nm or more or 300 nm or more. The thickness of the oxide insulating layer 150 in the second region A2 and the third region A3 is 100 nm or less. The thickness of the oxide insulating layer 150 in the second region A2 and the third region A3 may be 50 nm or less or 30 nm or less. For example, by setting the thickness of the oxide insulating layer 150 in the second region A2 and the third region A3 to be 50 nm or more and 100 nm or less, it is possible to introduce enough impurities into the oxide insulating layer 120 in the second region A2 and the third region A3 by ion implantation while securing the blocking function of hydrogen diffused from the insulating layer 170.

Although the configuration is described in which the thickness of the oxide insulating layer 150 in the first region A1 is the same as the thickness of the oxide insulating layer 150 in the second region A2 and the third region A3 is shown in FIG. 1, the present embodiment is not limited to this configuration. The thickness of the oxide insulating layer 150 in the first region A1 may be greater than the thickness of the oxide insulating layer 150 in the second region A2 and the third region A3. In this case, the oxide insulating layer 150 has a sidewall (second sidewall) along the gate electrode 160 in a plan view. The second sidewall is in contact with the insulating layer 170.

The oxide semiconductor layer 140 is divided into a source region S, a drain region D, and a channel region CH based on the pattern of the gate electrode 160. The source region S and the drain region D are regions corresponding to the second region A2. The channel region CH is a region corresponding to the first region A1. In a plan view, an end portion in the channel region CH is consistent with an end portion of the gate electrode 160. The oxide semiconductor layer 140 in the channel region CH has semiconductor properties. Each of the oxide semiconductor layer 140 in the source region S and the drain region D has conductive properties. That is, carrier concentrations of the oxide semiconductor layer 140 in the source region S and the drain region D are higher than a carrier concentration of the oxide semiconductor layer 140 in the channel region CH. The source electrode 201 and the drain electrode 203 contact the oxide semiconductor layer 140 in the source region S and the drain region D, respectively, and are electrically connected to the oxide semiconductor layer 140. The oxide semiconductor layer 140 may be a single-layer structure or a stacked structure.

In the present embodiment, although a top-gate transistor in which the gate electrode 160 is arranged above the oxide semiconductor layer 140 is exemplified as the semiconductor device 10, the semiconductor device 10 is not limited to this configuration. For example, as described above, the semiconductor device 10 may be a dual-gate transistor in which the light-shielding layer 105 functions as a gate in addition to the gate electrode 160. Alternatively, the semiconductor device 10 may be a bottom-gate transistor in which the light-shielding layer 105 mainly functions as a gate. The above configurations are merely embodiments, and the present invention is not limited to the above configurations.

As shown in FIG. 2, in a direction D1, the width of the light-shielding layer 105 is greater than the width of the gate electrode 160. The direction D1 is a direction connecting the source electrode 201 and the drain electrode 203, and is a direction indicating a channel length L of the semiconductor device 10. Specifically, a length in the direction D1 in the region (the channel region CH) where the oxide semiconductor layer 140 and the gate electrode 160 overlap is the channel length L, and a width in a direction D2 in the channel region CH is a channel width W. The light-shielding layer 105 and the gate electrode 160 extend in the direction D2. An opening 161 is arranged in the nitride insulating layer 110, the oxide insulating layer 120, and the oxide insulating layer 150, and the light-shielding layer 105 and the gate electrode 160 are connected via the opening 161.

In FIG. 2, although a configuration in which the source/drain electrode 200 does not overlap the light-shielding layer 105 and the gate electrode 160 in a plan view is exemplified, the configuration is not limited to this configuration. For example, in a plan view, the source/drain electrode 200 may overlap at least one of the light-shielding layer 105 and the gate electrode 160. The above configuration is merely an embodiment, and the present invention is not limited to the above configuration.

### [1-2. Material of Each Member of Semiconductor Device 10]

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the light-shielding layer 105, the gate electrode 160, and the source/drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as these members. The above-described materials may be used in a single layer or a stacked layer as the light-shielding layer 105, the gate electrode 160, and the source/drain electrode 200. A material other than the above-described metal materials may be used as the light-shielding layer 105 if conductivity is not required. For example, a black matrix such as a black resin may be used as the light-shielding layer 105. The light-shielding layer 105 may be a single-layer structure or a stacked structure. For example, the light-shielding layer 105 may be a stacked structure of a red color filter, a green color filter, and a blue color filter.

Common insulating materials are used as the nitride insulating layer 110, the oxide insulating layer 120, the oxide insulating layer 150, the nitride insulating layer 155, and the insulating layers 170 and 180. For example, inorganic insulating layers such as silicon oxide (SiOₓ), silicon oxynitride (SiOₓN_{y}), aluminum oxide (AlOₓ), and aluminum oxynitride (AlOₓN_{y}) are used as the oxide insulating layers 120 and 150 and the insulating layer 180. Inorganic insulating layers such as silicon nitride (SiNₓ), silicon nitride oxide (SiNₓO_{y}), aluminum nitride (AlNₓ), and aluminum nitride oxide (AlNₓO_{y}) are used as the nitride insulating layer 110 and the insulating layer 170. However, the inorganic insulating layer such as silicon oxide (SiOₓ), silicon oxynitride (SiOₓN_{y}), aluminum oxide (AlOₓ), or aluminum oxynitride (AlOₓN_{y}) may be used as the insulating layer 170. The inorganic insulating layer such as silicon nitride (SiNₓ), silicon nitride oxide (SiNₓO_{y}), aluminum nitride (AlNₓ), and aluminum nitride oxide (AlNₓO_{y}) may be used as the insulating layer 180.

An insulating layer having a function of releasing oxygen by a heat treatment is used as the oxide insulating layer 120. That is, an oxide insulating layer containing excess oxygen is used as the oxide insulating layer 120. For example, the temperature of a heat treatment at which the oxide insulating layer 120 releases oxygen is 600° C. or lower, 500° C. or lower, 450° C. or lower, or 400° C. or lower. That is, for example, the oxide insulating layer 120 releases oxygen at a heat treatment temperature performed in a manufacturing process of the semiconductor device 10 when a glass substrate is used as the substrate 100. Similar to the oxide insulating layer 120, an insulating layer having a function of releasing oxygen by a heat treatment may be used for at least one of the insulating layers 170 and 180.

An insulating layer with few defects is used as the oxide insulating layer 150. For example, when a composition ratio of oxygen in the oxide insulating layer 150 is compared with a composition ratio of oxygen in an insulating layer (hereinafter referred to as “other insulating layer”) having a composition similar to that of the oxide insulating layer 150, the composition ratio of oxygen in the oxide insulating layer 150 is closer to the stoichiometric ratio with respect to the insulating layer than the composition ratio of oxygen in the other insulating layer. Specifically, in the case where silicon oxide (SiOₓ) is used for each of the oxide insulating layer 150 and the insulating layer 180, the composition ratio of oxygen in the silicon oxide used as the oxide insulating layer 150 is close to the stoichiometric ratio of silicon oxide as compared with the composition ratio of oxygen in the silicon oxide used as the insulating layer 180. For example, a layer in which no defects are observed when evaluated by electron-spin resonance (ESR) may be used as the oxide insulating layer 150.

SiOₓN_{y} and AlOₓN_{y} described above are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

A metal oxide having semiconductor properties may be used as the oxide semiconductor layer 140. For example, an oxide semiconductor containing indium (In), gallium (Ga), zinc (Zn), and oxygen (O) may be used as the oxide semiconductor layer 140. For example, an oxide semiconductor having a composition ratio of In:Ga:Zn:O=1:1:1:4 may be used as the oxide semiconductor layer 140. However, the oxide semiconductor containing In, Ga, Zn and O used in the present embodiment is not limited to the above-described composition. An oxide semiconductor having a composition other than the above may be used as the oxide semiconductor. For example, an oxide semiconductor layer having a higher ratio of In than those described above may be used to improve mobility. On the other hand, in order to increase the bandgap and reduce the effect of photoirradiation, an oxide semiconductor layer having a higher ratio of Ga than those described above may be used.

Gallium (Ga), zinc (Zn), aluminum (Al), hafnium (Hf), yttrium (Y), zirconia (Zr), and lanthanoids may be used as the oxide semiconductor layer 140 in addition to indium. Elements other than those described above may be used as the oxide semiconductor layer 140.

Other elements may be added to the oxide semiconductor containing In, Ga, Zn, and O as the oxide semiconductor layer 140, and metal elements such as Al, Sn may be added. In addition to the above oxide semiconductor, an oxide semiconductor (IGO) containing In, Ga, an oxide semiconductor (IZO) containing In, Zn, an oxide semiconductor (ITZO) containing In, Sn, Zn, and an oxide semiconductor containing In, W may be used as the oxide semiconductor layer 140.

In the case where the proportion of the indium element is high, the oxide semiconductor layer 140 is easily crystallized. As described above, by using a material in which the ratio of the indium element with respect to the total metal element is 50% or more in the oxide semiconductor layer 140, it is possible to obtain the oxide semiconductor layer 140 having a polycrystalline structure. The oxide semiconductor layer 140 preferably contains gallium as a metal element other than indium. Gallium belongs to the same Group 13 element as indium. Therefore, the crystallinity of the oxide semiconductor layer 140 is not inhibited by gallium, and the oxide semiconductor layer 140 has a polycrystalline structure.

Although a detailed method of manufacturing the oxide semiconductor layer 140 will be described later, the oxide semiconductor layer 140 can be formed using a sputtering method. A composition of the oxide semiconductor layer 140 formed by the sputtering method depends on a composition of a sputtering target. Even though the oxide semiconductor layer 140 has a polycrystalline structure, the composition of the sputtering target is substantially consistent with the composition of the oxide semiconductor layer 140. In this case, the composition of the metal element of the oxide semiconductor layer 140 can be specified based on the composition of the metal element of the sputtering target.

In the case where the oxide semiconductor layer 140 has a polycrystalline structure, a composition of the oxide semiconductor layer may be specified using X-ray diffraction (X-ray Diffraction: XRD). Specifically, a composition of the metal element of the oxide semiconductor layer can be specified based on the crystalline structure and the lattice constant of the oxide semiconductor layer obtained by the XRD method. Furthermore, the composition of the metal element of the oxide semiconductor layer 140 can also be identified using fluorescent X-ray analysis, Electron Probe Micro Analyzer (EPMA) analysis, or the like. However, the oxygen element contained in the oxide semiconductor layer 140 may not be specified by these methods because the oxygen element varies depending on the sputtering process conditions.

As described above, the oxide semiconductor layer 140 may have an amorphous structure or a polycrystalline structure. The oxide semiconductor having a polycrystalline structure can be manufactured using a Poly-OS (Poly-crystalline Oxide Semiconductor) technique. In the following, the oxide semiconductor having the polycrystalline structure may be described as the Poly-OS when distinguished from the oxide semiconductor having the amorphous structure.

As described above, in the case where a metal oxide layer is arranged between the oxide insulating layer 120 and the oxide semiconductor layer 140, a metal oxide containing aluminum as the main component is used as the metal oxide layer. For example, inorganic insulating layers such as aluminum oxide (AlOₓ), aluminum oxynitride (AlOₓN_{y}) and aluminum nitride oxide (AlNₓO_{y}) are used as the metal oxide layer. The “metal oxide layer containing aluminum as the main component” means that the ratio of aluminum contained in the metal oxide layer is 1% or more of the total amount of the metal oxide layer. The proportion of aluminum contained in the metal oxide layer may be 5% or more and 70% or less, 10% or more and 60% or less, or 30% or more and 50% or less of the total amount of the metal oxide layer. The ratio may be a mass ratio or a weight ratio.

### [1-3. Configuration of Hydrogen-Trapping Region]

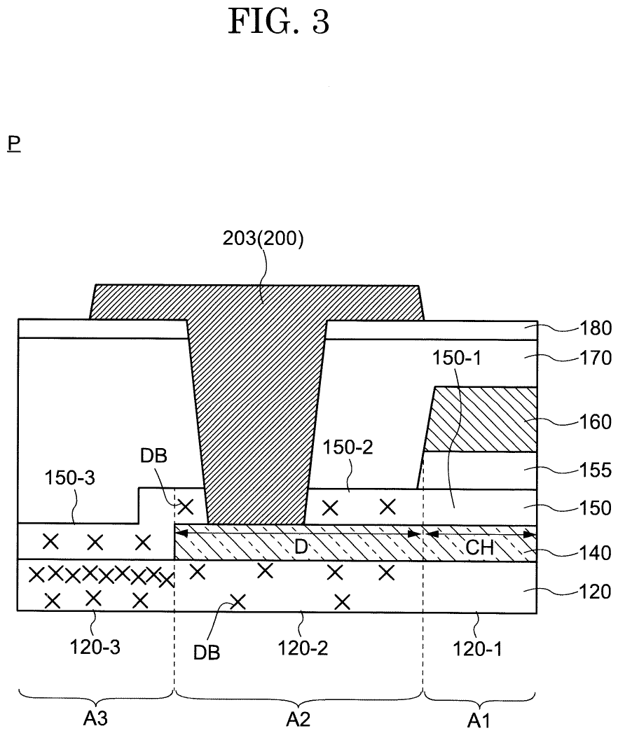

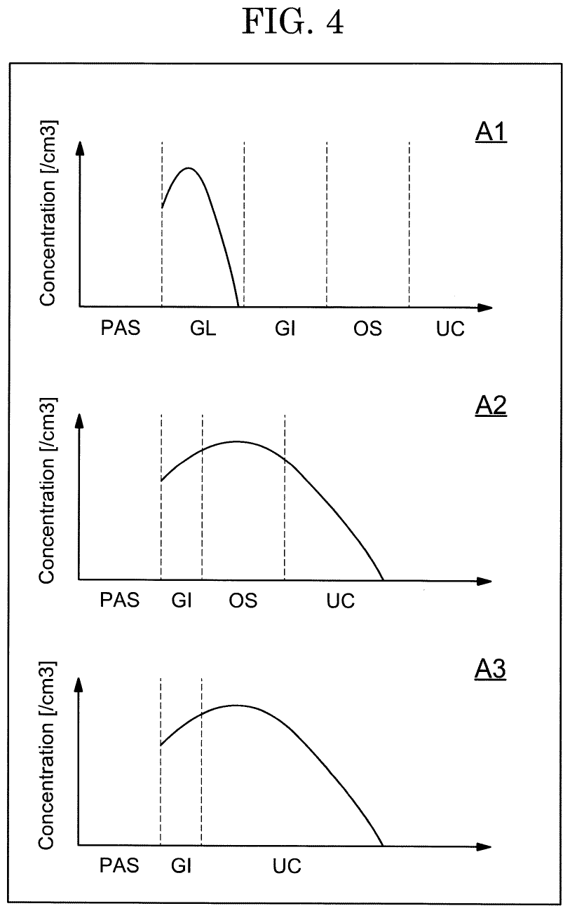

A hydrogen-trapping region is formed in the oxide insulating layers 120 and 150. Therefore, a configuration of the hydrogen-trapping region formed in the oxide insulating layers 120 and 150 will be described with reference to FIG. 3 and FIG. 4. FIG. 3 is a schematic partially enlarged cross-sectional view showing a configuration of a semiconductor device according to an embodiment of the present invention. Specifically, FIG. 3 is an enlarged cross-sectional view of a region P in FIG. 1. Although the region P shown in FIG. 3 is a region in the vicinity of the drain region D, the vicinity of the source region S also has the same configuration as the region P.

The oxide insulating layers 120 and 150 are divided into the first region A1, the second region A2, and the third region A3. The oxide insulating layer 120 in each region is denoted as oxide insulating layers 120-1, 120-2, and 120-3, respectively. Similarly, the oxide insulating layer 150 in each region is denoted as oxide insulating layers 150-1, 150-2, and 150-3, respectively. The oxide insulating layers 120-1 and 120-2 are in contact with the oxide semiconductor layer 140. The oxide insulating layer 120-3 is in contact with the oxide insulating layer 150-3. The oxide insulating layer 150-1 is in contact with the oxide semiconductor layer 140 in the channel region CH. The oxide insulating layer 150-2 is in contact with the oxide semiconductor layer 140 and the insulating layer 170 in the drain region D. The oxide insulating layer 150-3 is located outside the drain region D and is in contact with the oxide insulating layer 120 and the insulating layer 170.

Although details will be described later, the oxide semiconductor layer 140 in the source region S and the drain region D is formed by ion implantation of impurities using the gate electrode 160 as a mask. For example, boron (B), phosphorus (P), argon (Ar), nitrogen (N), or the like is used as the impurity. Oxygen defects are generated in the oxide semiconductor layer 140 in the source region S and the drain region D by ion implantation. The resistance of the oxide semiconductor layer 140 in the source region S and the drain region D is reduced by trapping hydrogen in the generated oxygen defects. Since a silicon nitride layer contains more hydrogen than a silicon oxide layer, for example, the use of silicon nitride as the insulating layer 170 can reduce the resistance of the oxide semiconductor layer 140 in the source region S and the drain region D.

Since the ion implantation is performed through the oxide insulating layer 150, a dangling bond-defect DB is generated in the oxide insulating layer 150 by the ion implantation. In the second region A2, the ion-implanted impurities reach the oxide insulating layer 120 beyond the oxide insulating layer 150 and the oxide semiconductor layer 140. Similarly, in the third region A3, the ion-implanted impurities reach the oxide insulating layer 120 beyond the oxide insulating layer 150. Therefore, the dangling bond-defect DB is also generated in the oxide insulating layer 120 in the second region A2 and the third region A3.

Since the impurity is ion-implanted using the gate electrode 160 as a mask, no impurity is implanted into the oxide insulating layer 120-1 and the oxide insulating layer 150-1 in the first region A1. Therefore, no dangling bond-defect DB is generated in the oxide insulating layer 120-1 and the oxide insulating layer 150-1. On the other hand, as described above, the dangling bond-defect DB is generated in the oxide insulating layers 120-2 and 120-3 and the oxide insulating layers 150-2 and 150-3. For example, in the case where silicon oxide is used as the oxide insulating layers 120 and 150, the dangling bond-defect DB of silicon is formed in the oxide insulating layers 120-2 and 120-3 and the oxide insulating layers 150-2 and 150-3.

The dangling bond-defect DB formed in the oxide insulating layer 120 and the oxide insulating layer 150 traps hydrogen. In other words, in the semiconductor device 10, the oxide insulating layers 120-2 and 120-3 and the oxide insulating layers 150-2 and 150-3 function as the hydrogen-trapping region. Therefore, for example, hydrogen diffused from the insulating layer 170 at the time of deposition of the insulating layer 170 is trapped in the dangling bond-defect DB in these insulating layers, so that it is possible to suppress hydrogen from entering the oxide semiconductor layer 140 in the channel region CH. Therefore, in the condition after the insulating layer 170 is formed, the hydrogen concentrations of the oxide insulating layers 120-2 and 120-3 are higher than the hydrogen concentration of the oxide insulating layer 120-1. Similarly, the hydrogen concentrations of the oxide insulating layers 150-2 and 150-3 are higher than the hydrogen concentration of the oxide insulating layer 150-1.

Since the dangling bond-defect DB is formed by ion implantation, the oxide insulating layers 120-2 and 120-3 and the oxide insulating layers 150-2 and 150-3 contain impurities introduced by ion implantation. The distribution of the amount of dangling bond-defect DB formed in the oxide insulating layers 120-2 and 120-3 and the oxide insulating layers 150-2 and 150-3 corresponds to a concentration profile of the impurity contained therein. That is, the position and amount of the dangling bond-defect DB can be adjusted by adjusting the profile of the impurity obtained by the ion implantation.

Although details will be described later, it is effective to form the dangling bond-defect DB in the oxide insulating layer 120 in order to suppress the occurrence of an abnormality in the electrical characteristics of the semiconductor device 10 due to penetration of hydrogen into the oxide semiconductor layer 140 in the channel region CH. Therefore, impurities need to be implanted to reach the oxide insulating layer 120 through the oxide insulating layer 150.

For example, in the case of the semiconductor device in which the gate insulating layer is required to withstand a high voltage, the thickness of the gate insulating layer (the insulating layer between the oxide semiconductor layer and the gate electrode) is required to be 200 nm or more. On the other hand, in the case where the impurity is caused to reach the oxide insulating layer 120 by ion implantation, the thickness of the gate insulating layer in the second region A2 and the third region A3 is required to be 100 nm or less because there is a limitation due to the acceleration voltage in an ion implantation device. In order to satisfy these requirements, the above-described configuration is employed.

FIG. 4 is a graph showing profiles of impurity concentrations in the first region A1 to the third region A3 in a semiconductor device according to the embodiment of the present invention. The vertical axes of each of the three concentration profiles shown in FIG. 4 indicate the concentration of impurities per unit volume (Concentration [/cm³]), and the horizontal axes indicate the name of the layer in a depth direction. The “UC” in the horizontal axis corresponds to the oxide insulating layer 120 and the nitride insulating layer 110. The “OS” corresponds to the oxide semiconductor layer 140. The “GI” in the first region A1 corresponds to the oxide insulating layer 150 and the nitride insulating layer 155. The “GI” in the second region A2 and the third region A3 corresponds to the oxide insulating layer 150. The “GL” corresponds to the gate electrode 160. The “PAS” corresponds to the insulating layer 170.

As shown in FIG. 4, in the first region A1, the concentration profile of the impurity has a peak in the gate electrode 160 (GL). Therefore, in the depth direction in the first region A1, the amount of impurities contained in a predetermined position of the gate electrode 160 is greater than each of the amount of impurities contained in a predetermined position of the oxide insulating layer 150, the amount of impurities contained in a predetermined position of the oxide semiconductor layer 140, and the amount of impurities contained in a predetermined position of the oxide insulating layer 120. The above “depth direction” means a thickness direction of each layer. The metal material has a high stopping power against impurities introduced by ion implantation. If the metal material is used as the gate electrode 160, the impurities are blocked by the gate electrode 160 and do not reach the oxide insulating layer 150 (GI). Therefore, the dangling bond-defect DB due to the introduction of impurities is not formed in the oxide insulating layers 120 and 150 and the oxide insulating layer 120 in the first region A1. However, the impurities may reach the oxide insulating layer 150 as long as the electrical characteristics of the semiconductor device 10 are not affected.

In the second region A2, the concentration profile of the impurity has peaks in the oxide semiconductor layer 140 (OS). Therefore, in the depth in the second region A2, the amount of impurities contained in the predetermined position of the oxide semiconductor layer 140 is greater than the amount of impurities contained in the predetermined position of the oxide insulating layer 150, and each of the amounts of impurities contained in the predetermined position of the oxide insulating layer 120. Since the purpose of introducing impurities is to reduce the resistance of the oxide semiconductor layer 140 in the source region S and the drain region D, the ion implantation condition is set so as to have the above-described concentration profile. The amount of impurities contained in the oxide semiconductor layer 140 in the second region A2 is greater than the amount of impurities contained in the oxide semiconductor layer 140 in the first region A1. Similarly, the amount of impurities contained in the oxide insulating layer 120 (UC) in the second region A2 is greater than the amount of impurities contained in the oxide insulating layer 120 in the first region A1. Similarly, the amount of impurities contained in the oxide insulating layer 150 (GI) in the second region A2 is greater than the amount of impurities contained in the oxide insulating layer 150 in the first region A1.

In the second region A2, impurities are also introduced into the oxide insulating layers 120 and 150 reflecting the concentration profile of the impurity as described above. Therefore, the dangling bond-defect DB associated with the introduction of impurities is formed in the oxide insulating layers 120 and 150. However, in the second region A2, the concentration of impurities present in the oxide insulating layers 120 and 150 is lower than the concentration of impurities present in the oxide semiconductor layer 140.

In the third region A3, the concentration profile of the impurity has a peak in the oxide insulating layer 120 (UC). Therefore, in the depth direction in the third region A3, the amount of impurities contained in the predetermined position of the oxide insulating layer 120 is greater than the amount of impurities contained in the predetermined position of the oxide insulating layer 150. In the third region A3, the oxide semiconductor layer 140 is not arranged on the oxide insulating layer 120. Further, in the second region A2 and the third region A3, the thickness of the oxide insulating layer 150 is the same. As a result, instead of the peak of the concentration profile being present in the oxide semiconductor layer 140 in the second region A2, the peak of the concentration profile is present in the oxide insulating layer 120 in the third region A3. That is, the amount of impurities contained in the oxide insulating layer 120 in the third region A3 is greater than the amount of impurities contained in the oxide insulating layer 120 in the first region A1 and greater than the amount of impurities contained in the oxide insulating layer 120 in the second region A2. Similarly, the amount of impurities contained in the oxide insulating layer 150 in the third region A3 is greater than the amount of impurities contained in the oxide insulating layer 150 in the first region A1, and is equivalent to the amount of impurities contained in the predetermined position of the oxide insulating layer 150 in the depth direction in the second region A2.

According to the concentration profile of the impurity as described above, the dangling bond-defect DB associated with the introduction of the impurity is formed in the oxide insulating layer 120. As described above, since the peak of the concentration profile is present in the oxide insulating layer 120 in the third region A3, the amount of dangling bond-defect DB present in the oxide insulating layer 120 in the third region A3 is greater than the amount of dangling bond-defect DB present in the oxide insulating layer 120 in the second region A2. Therefore, the oxide insulating layer 120 in the third region A3 can trap more hydrogen than the oxide insulating layer 150 in the third region A3 and trap more hydrogen than the oxide insulating layer 120 in the second region A2.

In the present embodiment, in the depth direction of the third region A3, the amount of impurities contained at a predetermined position in the oxide insulating layer 120 is 1×10¹⁶/cm³ or more, 1×10¹⁷/cm³ or more, or 1×10¹⁸/cm³ or more. The predetermined position may be a peak position of the concentration profile or a position corresponding to an interface between the oxide insulating layer 120 and the oxide insulating layer 150. Alternatively, the predetermined position may be a position moved by a predetermined depth from a position corresponding to the interface toward the oxide insulating layer 120.

In the present embodiment, although the configuration in which the amount of impurities contained in the oxide insulating layer 120 in the third region A3 is larger than the amount of impurities contained in the oxide insulating layer 120 in the second region A2 has been exemplified, the configuration is not limited to this configuration. Similarly, in the present embodiment, although the configuration in which the peak of the impurity concentration profile in the third region A3 is present in the oxide insulating layer 120 has been exemplified, the configuration is not limited to this configuration. The peaks may be present in the oxide insulating layer 150. That is, in the third region A3, the amount of impurities contained in the oxide insulating layer 120 may be smaller than the amount of impurities contained in the oxide insulating layer 150. In this case, the peak of the impurity concentration profile in the second region A2 is also present in the oxide insulating layer 150. That is, in the second region A2, the amount of impurities contained in the oxide semiconductor layer 140 may be smaller than the amount of impurities contained in the oxide insulating layer 150. Further, in the present embodiment, although the configuration in which the peak of the impurity concentration profile in the second region A2 is present in the oxide semiconductor layer 140 has been exemplified, the configuration is not limited to this configuration. The peak may be present in the oxide insulating layer 120.

Referring to FIG. 1 and FIG. 2, the channel region CH corresponds to the first region A1, the source region S and the drain region D correspond to the second region A2, and regions other than the channel region CH, the source region S, and the drain region D correspond to the third region CH. That is, the channel region CH is sandwiched by the second region A2 and surrounded by the third region A3. Therefore, for example, hydrogen diffused from the insulating layer 170 at the time of deposition of the insulating layer 170 is trapped by the dangling bond-defect DB formed in the oxide insulating layers 120 and 150 formed in the second region A2 and the third region A3 located around the channel region CH. As a result, it is possible to suppress the hydrogen from entering the oxide semiconductor layer 140 in the channel region CH.

### [1-4. Method for Manufacturing Semiconductor Device 10]

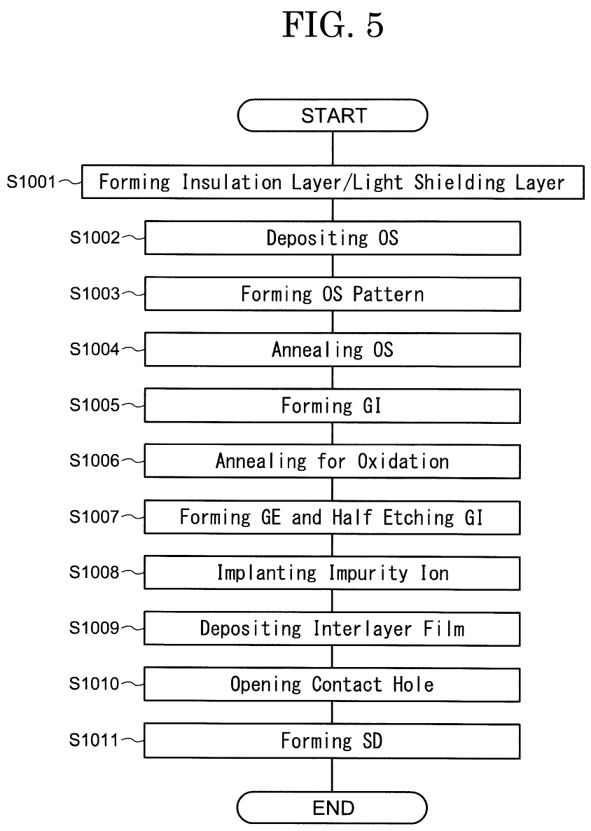

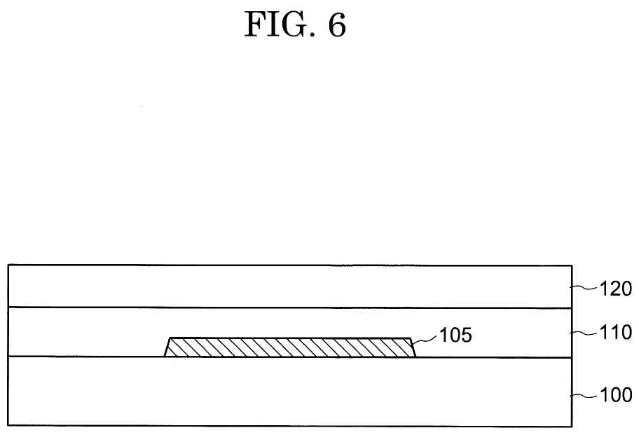

A method for manufacturing a semiconductor device 10 according to an embodiment of the present invention will be described with reference to FIG. 5 to FIG. 13. FIG. 5 is a sequence diagram showing a method for manufacturing a semiconductor device according to an embodiment of the present invention. FIG. 6 to FIG. 13 are cross-sectional views showing a method for manufacturing a semiconductor device according to an embodiment of the present invention.

As shown in FIG. 5 and FIG. 6, the light-shielding layer 105 is formed on the substrate 100 as the bottom-gate, and the nitride insulating layer 110 and the oxide insulating layer 120 are formed on the light-shielding layer 105 (“Forming Insulation Layer/Light Shielding Layer” in step S1001 of FIG. 5). For example, silicon nitride is formed as the nitride insulating layer 110. For example, silicon oxide is formed as the oxide insulating layer 120. The nitride insulating layer 110 and the oxide insulating layer 120 are deposited by a CVD (Chemical Vapor Deposition) method. For example, a thickness of the nitride insulating layer 110 is 50 nm or more and 500 nm or less, or 150 nm or more and 300 nm or less. A thickness of the oxide insulating layer 120 is 50 nm or more and 500 nm or less, or 150 nm or more and 300 nm or less.

Using silicon nitride as the nitride insulating layer 110 allows the nitride insulating layer 110 to block impurities that diffuse, for example, from the substrate 100 toward the oxide semiconductor layer 140. For example, the silicon oxide used as the oxide insulating layer 120 is silicon oxide having a physical property of releasing oxygen by a heat treatment.

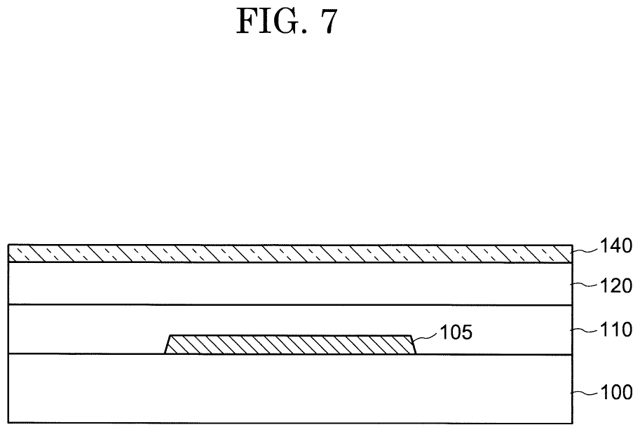

As shown in FIG. 5 and FIG. 7, the oxide semiconductor layer 140 is formed on the oxide insulating layer 120 (“Depositing OS” in step S1002 of FIG. 5). The oxide semiconductor layer 140 is deposited by the sputtering method or an atomic layer deposition method (ALD).

In the case where the metal oxide layer containing aluminum as the main component is arranged between the oxide insulating layer 120 and the oxide semiconductor layer 140, the metal oxide layer is also deposited by the sputtering method or an atomic-layer deposition method in the same manner as described above.

For example, a thickness of the oxide semiconductor layer 140 is 10 nm or more and 100 nm or less, 15 nm or more and 70 nm or less, or 20 nm or more and 40 nm or less. In the present embodiment, the thickness of the oxide semiconductor layer 140 is 30 nm. The oxide semiconductor layer 140 before the heat treatment (OS anneal) described later is amorphous.

When the oxide semiconductor layer 140 is crystallized by the OS anneal described later, the oxide semiconductor layer 140 after the deposition and before the OS anneal is preferably in an amorphous state (a state where the oxide semiconductor has few crystalline components). That is, the deposition condition of the oxide semiconductor layer 140 is preferred to be a condition such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals occur in the oxide semiconductor layer 140 immediately after the deposition process. There is a possibility that the microcrystals inhibit crystallization by a subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or lower, 70° C. or lower, 50° C. or lower, or 30° C. or lower. As described above, depositing the oxide semiconductor layer 140 while cooling the object to be deposited makes it possible to deposit the oxide semiconductor layer 140 with few crystalline components in a state immediately after the deposition. An oxygen partial pressure in the deposition conditions of the oxide semiconductor layer 140 is 2% or more and 20% or less, 3% or more and 15% or less, or 3% or more and 10% or less

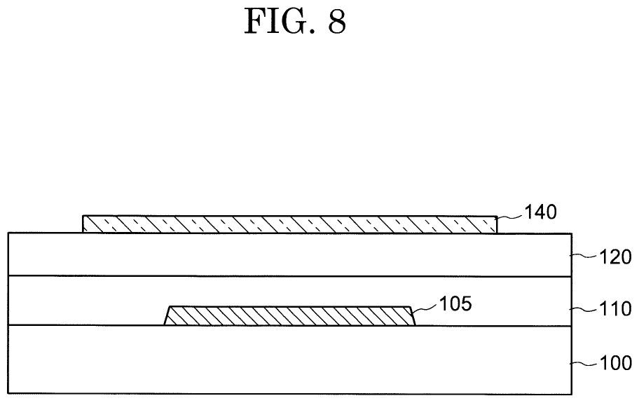

As shown in FIG. 5 and FIG. 8, a pattern of the oxide semiconductor layer 140 is formed (“Forming OS Pattern” in step S1003 of FIG. 5). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. The wet etching may include etching using an acidic etchant. For example, oxalic acid, PAN, sulfuric acid, hydrogen peroxide or hydrofluoric acid may be used as the etchant. Since the oxide semiconductor layer 140 in the step S1003 is amorphous, the oxide semiconductor layer 140 can be easily patterned into a predetermined shape by wet etching.

The pattern of the oxide semiconductor layer 140 is formed, and then a heat treatment (OS anneal) is performed on the oxide semiconductor layer 140 (“Annealing OS” in step S1004 of FIG. 5). In the OS anneal, the oxide semiconductor layer 140 is held at a predetermined reaching temperature for a predetermined time. The predetermined reaching temperature is 300° C. or higher and 500° C. or lower, or 350° C. or higher and 450° C. or lower. The holding time at the reaching temperature is 15 minutes or more and 120 minutes or less, or 30 minutes or more and 60 minutes or less. In the present embodiment, the oxide semiconductor layer 140 is crystallized by the OS anneal. However, the oxide semiconductor layer 140 does not necessarily have to be crystallized by the OS anneal.

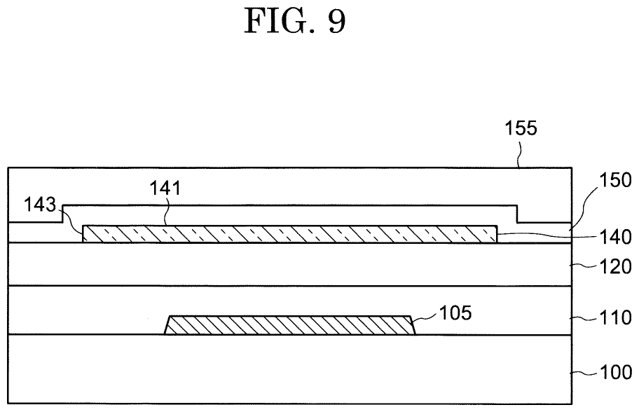

As shown in FIGS. 5 and 9, the oxide insulating layer 150 and the nitride insulating layer 155 are formed (“Forming GI” in step S1005 of FIG. 5). For example, silicon oxide is formed as the oxide insulating layer 150. For example, silicon nitride is formed as the nitride insulating layer 155. The oxide insulating layer 150 and the nitride insulating layer 155 are formed by the CVD method. For example, the oxide insulating layer 150 may be formed at a deposition temperature of 350° C. or higher in order to form an insulating layer with few defects as the insulating layer 150 as described above. For example, the total thickness of the oxide insulating layer 150 and the nitride insulating layer 155 is 200 nm or more and 500 nm or less, 200 nm or more and 400 nm or less, or 250 nm or more and 350 nm or less. For example, the thickness of the oxide insulating layer 150 is 100 nm or less, 50 nm or less, or 30 nm or less. After the oxide insulating layer 150 is deposited, an oxygen-implantation process may be performed on the oxide insulating layer 150. A metal oxide layer may be formed on the oxide insulating layer 150 by the sputtering method as the oxygen-implantation process.

A heat treatment (oxidation anneal) for supplying oxygen to the oxide semiconductor layer 140 is performed in a state where the oxide insulating layer 150 and the nitride insulating layer 155 are deposited on the oxide semiconductor layer 140 and the metal oxide layer 190 is deposited on the oxide insulating layer 150 (“Annealing for Oxidation” in step S1006 of FIG. 5). In the process from the deposition of the oxide semiconductor layer 140 to the deposition of the oxide insulating layer 150 on the oxide semiconductor layer 140, a large amount of oxygen vacancies occur in the upper surface 141 and the side surface 143 of the oxide semiconductor layer 140. Oxygen released from the oxide insulating layers 120 and the oxide insulating layer 150 is supplied to the oxide semiconductor layer 140 by the above-described oxidation anneal, and the oxygen vacancies are repaired. When the process of implanting oxygen into the gate insulation layer 150 is not performed, the oxidation anneal may be performed in a state where an insulating layer capable of releasing oxygen is formed by a heat treatment.

The metal oxide layer having aluminum as the main component may be formed on the oxide insulating layer 150 by sputtering in order to increase the amount of oxygenation supplied from the oxide insulating layer 150 to the oxide semiconductor layer 140, and then the oxidation annealing may be performed in that state. The use of aluminum oxide with high barrier properties against gas as the metal oxide layer can suppress the oxygen implanted into the oxide insulating layer 150 during oxidation annealing from being outwardly diffused. Oxygen implanted into the oxide insulating layer 150 is efficiently supplied to the oxide semiconductor layer 140 by forming and annealing the metal oxide layer. The metal oxide layer is removed after the oxidation annealing. The metal oxide layer may be formed on the nitride insulating layer 155 and the oxidation annealing may be performed in that state.

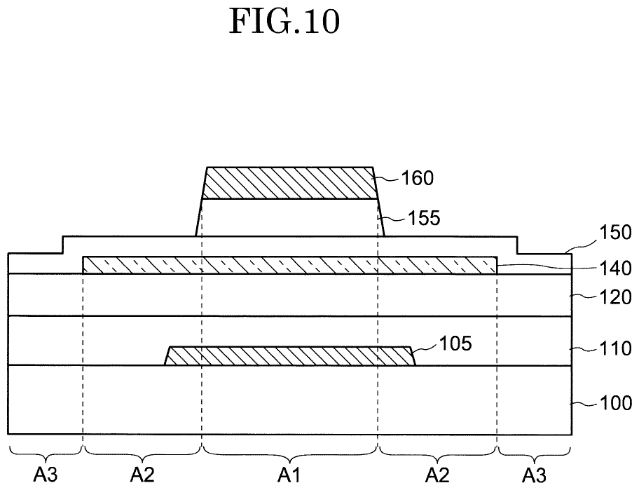

As shown in FIG. 5 and FIG. 10, the gate electrode 160 is formed and the gate insulating layer is half-etched (“Forming GE and Half Etching GI” in step S1007 of FIG. 5). Specifically, in S1007, only the nitride insulating layer 155 is etched so that the oxide insulating layer 150 remains. The gate electrode 160 is deposited by the sputtering method or the atomic layer deposition method. In the case where a voltage is supplied to the light-shielding layer 105, an opening is arranged in the nitride insulating layer 110, the oxide insulating layer 120, the oxide insulating layer 150, and the nitride insulating layer 155 before the deposition of the gate electrode 160, and the light-shielding layer 105 and the gate electrode 160 may be connected via the opening. The gate electrode 160 is patterned by a photolithography process. The gate electrode 160 and the nitride insulating layer 155 may be etched in the same process (the same conditions), and each may be etched in a different process (different conditions). That is, the half-etching of the gate insulating layer may be performed by over-etching in the etching process for the gate electrode 160, and may be performed by an etching different from the etching for the gate electrode 160 using the gate electrode 160 as a mask after the etching of the gate electrode 160.

In the present embodiment, although the configuration in which the thickness of the oxide insulating layer 150 in the first region A1 is the same as the thickness of the oxide insulating layer 150 in the second region A2 and the third region A3 has been exemplified, the configuration is not limited to this configuration. For example, the oxide insulating layer 150 in the second region A2 and the third region A3 may be over-etched by etching the nitride insulating layer 155, so that the thickness of the oxide insulating layer 150 in the second region A2 and the third region A3 may be smaller than the thickness of the oxide insulating layer 150 in the first region A1.

By half-etching of the gate insulating layer (etching of the nitride insulating layer 155), the thickness of the gate insulating layer (the thickness of the oxide insulating layer 150) in the second region A2 and the third region A3 is reduced to 100 nm or less. After the nitride insulating layer 155 is etched, the thickness of the oxide insulating layer 150 may be 100 nm or less, 50 nm or less, or 30 nm or less. The thickness of the oxide insulating layer 150 after etching is determined such that the impurity reaches the oxide insulating layer 120 by ion implantation, which will be described later.

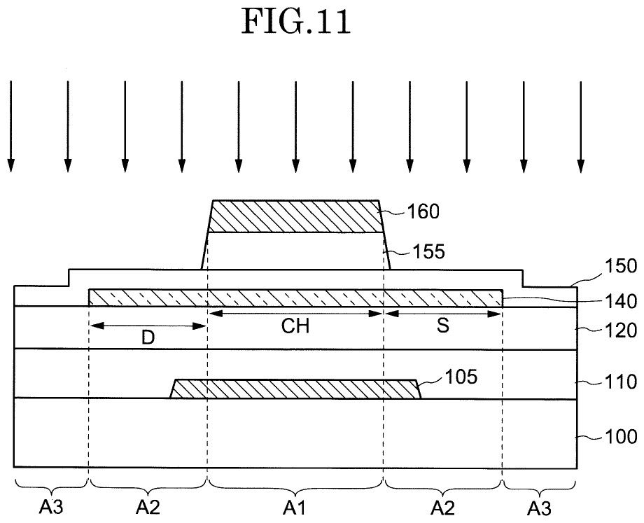

As shown in FIG. 11, with the gate electrode 160 patterned and the nitride insulating layer 155 in the second region A2 and the third region A3 etched, impurity ions are implanted into the oxide semiconductor layer 140 (“Implanting Impurity lon” in step S1008 of FIG. 5). Specifically, an impurity is implanted into the oxide insulating layer 120, the oxide semiconductor layer 140, and the oxide insulating layer 150 using the gate electrode 160 as a mask. For example, elements such as boron (B), phosphorus (P), argon (Ar), or nitrogen (N) are implanted into the oxide insulating layer 120, the oxide semiconductor layer 140, and the oxide insulating layer 150 by ion implantation.

In the oxide semiconductor layer 140 in the second region A2 that does not overlap the gate electrode 160, oxygen defects are generated by ion implantation. The resistance of the oxide semiconductor layer 140 in the second region A2 is reduced by trapping hydrogen in the generated oxygen defects. On the other hand, in the oxide semiconductor layer 140 in the first region A1 overlapping the gate electrode 160, impurities are not implanted, so that no oxygen defects are generated and resistance in the first region A1 is not lowered. Through the above steps, the channel region CH is formed in the oxide semiconductor layer 140 in the first region A1, and the source region S and the drain region D are formed in the oxide semiconductor layer 140 in the second region A2.

The dangling bond-defect DB is generated in the oxide insulating layer 120 and the oxide insulating layer 150 in the second region A2 and the third region A3 by the ion implantation. The position and amount of the dangling bond-defect DB can be controlled by adjusting the process parameters (for example, dose amount, acceleration voltage, plasma power, and the like) of the ion implantation. For example, the dose amount is 1×10¹⁴/cm² or more, 5×10¹⁴/cm² or more, or 1×10¹⁵/cm² or more. For example, the acceleration voltage is greater than 10 keV, 15 keV or more, or 20 keV or more.

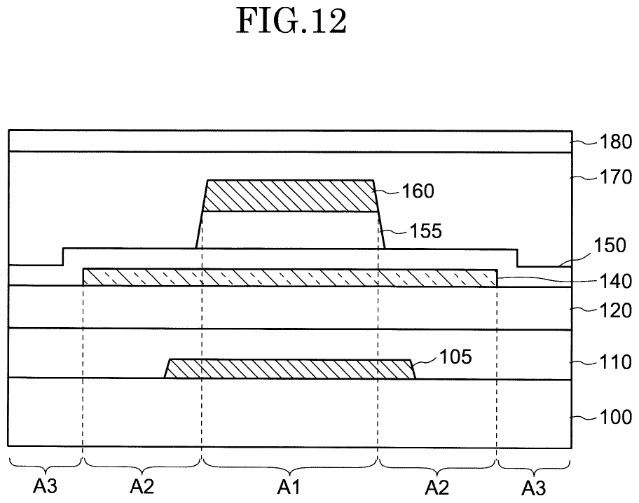

As shown in FIG. 5 and FIG. 12, the insulating layers 170 and 180 are deposited on the oxide insulating layer 150 and the gate electrode 160 as interlayer films (“Depositing Interlayer Film” in step S1009 of FIG. 5). The insulating layers 170 and 180 are deposited by the CVD method. For example, a silicon nitride layer is formed as the insulating layer 170, and a silicon oxide layer is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

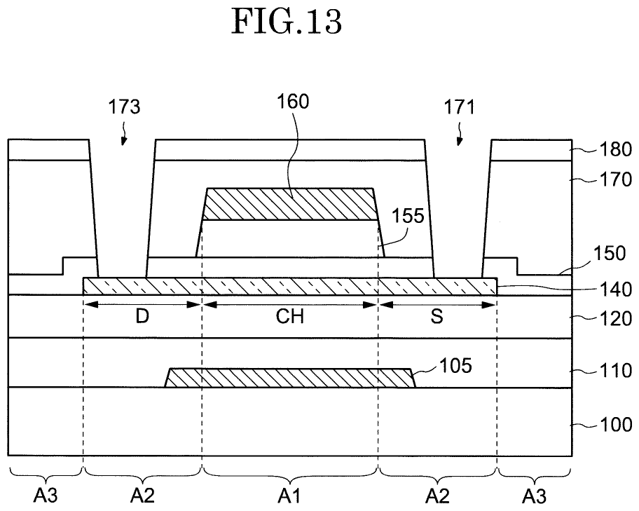

As shown in FIG. 5 and FIG. 13, the openings 171 and 173 are formed in the oxide insulating layer 150 and the insulating layers 170 and 180 (“Opening Contact Hole” in step S1010 of FIG. 5). The oxide semiconductor layer 140 in the source area S is exposed by the opening 171. The oxide semiconductor layer 140 in the drain area D is exposed by the opening 173. The semiconductor device 10 shown in FIG. 1 is completed by forming the source/drain electrode 200 on the oxide semiconductor layer 140 exposed by the openings 171 and 173 and on the insulating layer 180 (“Forming SD” in step S1011 of FIG. 5).

In the conventional configuration, the gate insulating layer is composed only of the oxide insulating layer. Therefore, the half-etching has been performed by setting the etching time based on a previously measured etching rate for the oxide insulating layer. However, in this method, it is difficult to control the thickness of the insulating layer in the second region A2 and the third region A3. Furthermore, in the conventional configuration, since the gate insulating layer is composed only of the oxide insulating layer, the oxygen in the oxide insulating layer used as the gate insulating layer is absorbed by the metal used as the gate electrode, and the amount of oxygen supplied from the oxide insulating layer to the oxide semiconductor layer is reduced when the gate insulating layer is deposited. In order to solve this problem, in the conventional configuration, measures such as arranging titanium in the lowermost layer of the gate electrode have been taken. However, titanium has a problem in that the etching rate for dry etching using a fluorine-based process gas, which is a dry etching for a general metal, is low and the throughput is lowered.

On the other hand, in the method for manufacturing the semiconductor device 10 according to the present embodiment, when the nitride insulating layer 155 is removed and the oxide insulating layer 150 is exposed in the etching process with respect to the nitride insulating layer 155, the spectrum of plasma emission generated during dry etching changes. Therefore, by analyzing the spectrum, it is possible to detect the timing at which the nitride insulating layer 155 is removed. Therefore, the thickness of the oxide insulating layer 150 in the second region A2 and the third region A3 can be accurately controlled. Furthermore, since the nitride insulating layer 155 on the oxide insulating layer 150 suppresses oxygen from diffusing upward from the oxide insulating layer 150 during the deposition of the gate electrode 160, there is no need to arrange titanium in the lowermost layer of the gate electrode.

### [1-5. Hydrogen-Trapping in Dangling Bond-Defect DB]

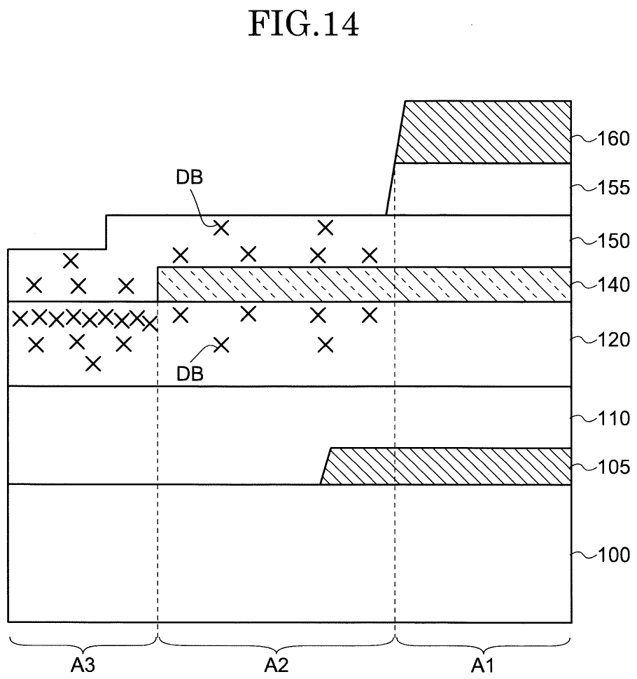

Referring to FIG. 4, FIG. 5, and FIG. 14, an impurity is implanted into the oxide insulating layer 150 (GI) and the oxide insulating layer 120 (UC) in the second region A2 and the third region A3 by the ion implantation in step S1008. This impurity ion implantation generates a dangling bond defect DB in the oxide insulating layers 120 and 150 in the second region A2 and the third region A3. In other words, the oxide insulating layers 120 and 150 contain impurities such as boron (B), phosphorus (P), argon (Ar), or nitrogen (N). In the present embodiment, of the oxide insulating layers 120 and 150 in the second region A2 and the third region A3, the amount of impurities contained in the oxide insulating layer 120 in the third region A3 is the largest. The amount of impurities contained in the oxide insulating layer 150 in the second region A2 and the third region A3 is the same. The dangling bond defect DB formed in the oxide insulating layers 120 and 150 when the impurities are introduced as described above is schematically shown in FIG. 14.

In order for the insulating layer 170 to have a function of blocking impurities diffused from above, the insulating layer 170 is preferably a dense film with few defects. In order to obtain such the insulating layer 170, the insulating layer 170 needs to be deposited at a high temperature. For example, in the case where the silicon nitride layer is deposited as the insulating layer 170 at a high temperature, a large amount of hydrogen is contained in the insulating layer 170, so that a large amount of hydrogen is diffused from the insulating layer 170 to the oxide insulating layer 150 due to the deposition temperature. Therefore, in the case where the hydrogen-trapping region is not formed in the oxide insulating layers 120 and 150, hydrogen diffuses not only into the oxide semiconductor layer 140 in the source region S and the drain region D but also into the semiconductor layer 140 in the channel region CH through the oxide insulating layers 120 and 150.

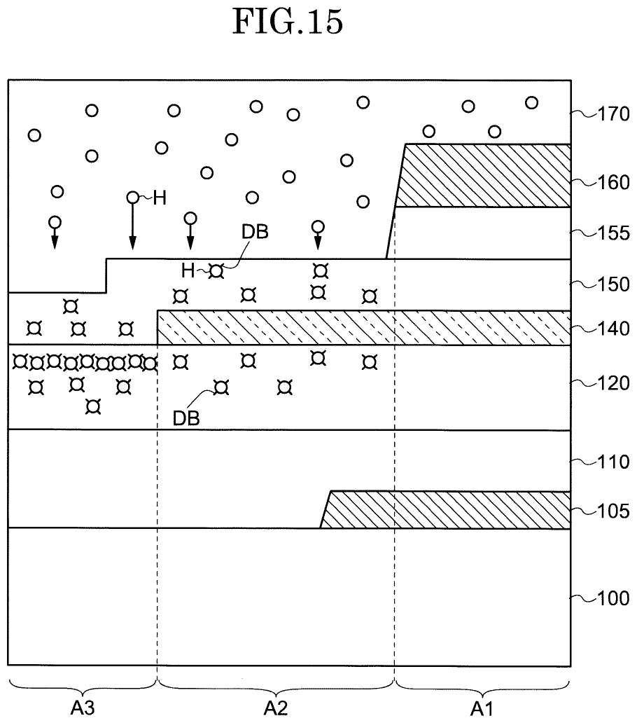

In step S1008, in the case where the dangling bond-defect DB shown in FIG. 14 is formed in the oxide insulating layers 120 and 150, as shown in FIG. 15, hydrogen H diffused from the insulating layer 170 at the time of deposition of the insulating layer 170 is trapped by the dangling bond-defect DB (“o” is superimposed on “x”). Therefore, in step S1009, it is possible to suppress the hydrogen H diffused from the insulating layer 170 at the time of deposition or after the deposition from entering the oxide semiconductor layer 140 in the channel region CH. Therefore, a film containing a large amount of hydrogen can be used as the insulating layer 170, so that the insulating layer 170 having a high impurity blocking function can be realized. Furthermore, the resistance of the oxide semiconductor layer 140 in the source region S and the drain region D can be sufficiently reduced.

In the present embodiment, among the oxide insulating layers 120 and 150 in the second region A2 and the third region A3, the amount of hydrogen H trapped in the oxide insulating layer 120 in the third region A3 is the largest. The amount of hydrogen H trapped in the oxide insulating layer 150 is the same in the second region A2 and the third region A3.

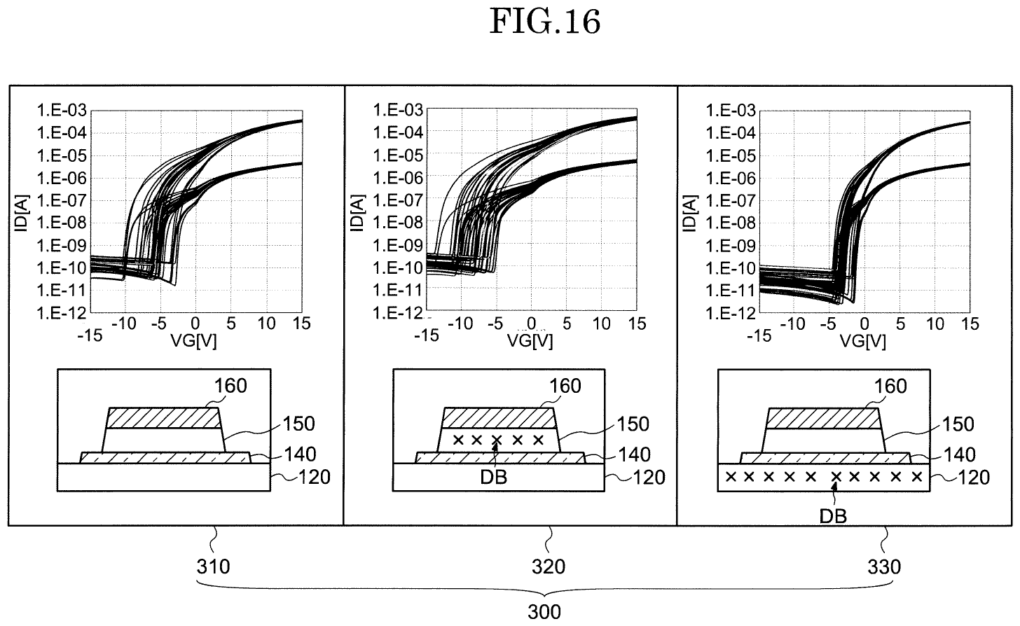

FIG. 16 is a schematic cross-sectional view illustrating effects of the hydrogen-trapping and a diagram showing electrical characteristics of a semiconductor device according to an embodiment of the present invention. The electrical characteristics shown in FIG. 16 show a result 300 of investigating the influence of the position (layer) where the hydrogen trap is formed on the electrical characteristics. The electrical characteristics indicated by 310 in FIG. 16 are electrical characteristics in the case where the hydrogen trap is not formed (relatively few) in both the oxide insulating layer 120 and the oxide insulating layer 150. The electrical characteristics indicated by 320 in FIG. 16 are electrical characteristics in the case where the hydrogen trap is formed only in the oxide insulating layer 150. The electrical characteristics indicated by 330 in FIG. 16 are electrical characteristics in the case where the hydrogen trap is formed only in the oxide insulating layer 120.

The above-described hydrogen trap is not formed by ion implantation of impurities as in the present embodiment, but is formed by pseudo-adjusting the deposition condition of each insulating layer. In the configuration of FIG. 16, silicon oxide layers are used as the oxide insulating layer 120 and the oxide insulating layer 150. It is known that when a silicon oxide layer is formed under a condition containing excessive oxygen, the silicon oxide layer contains many hydrogen traps. That is, under the condition indicated by 320 in FIG. 16, a silicon oxide layer containing excess oxygen is used as the oxide insulating layer 150. In the condition indicated by 330 in FIG. 16, a silicon oxide layer containing excess oxygen is used as the oxide insulating layer 120. FIG. 16 is the same configuration as FIG. 1 except that the oxide insulating layer 150 in the region that does not overlap the gate electrode 160 has been removed and that the nitride insulating layer 155 is not arranged.

As shown in 310 in FIG. 16, in the case where the hydrogen trap is not formed in both the oxide insulating layer 120 and the oxide insulating layer 150, humps in the electrical characteristics are confirmed. It is known that humps in electrical characteristics are generated when hydrogen enters the oxide semiconductor layer 140 in the channel region CH at the time of deposition of the insulating layer 170 film. As shown in 320 in FIG. 16, in the case where the hydrogen trap is formed only in the oxide insulating layer 150, the humps in the electrical characteristics are not improved. On the other hand, as shown in 330 in FIG. 16, in the case where the hydrogen trap is formed only in the oxide insulating layer 120, the humps in the electrical characteristics are reduced. From these results, it can be seen that it is essential to form the hydrogen trap in the oxide insulating layer 120 in order to suppress hydrogen from entering the oxide semiconductor layer 140 in the channel region CH at the time of deposition of the insulating layer 170.

In the present embodiment, as shown in FIG. 2, FIG. 4, and FIG. 14, many dangling bond-defects DB are formed in the oxide insulating layer 120 in the third region A3 surrounding the channel region CH. According to this configuration, it is possible to suppress hydrogen from entering the oxide semiconductor layer 140 in the channel region CH. As a result, it is possible to obtain the semiconductor device 10 having the electrical characteristics in which the humps are suppressed.

### 2. Second Embodiment

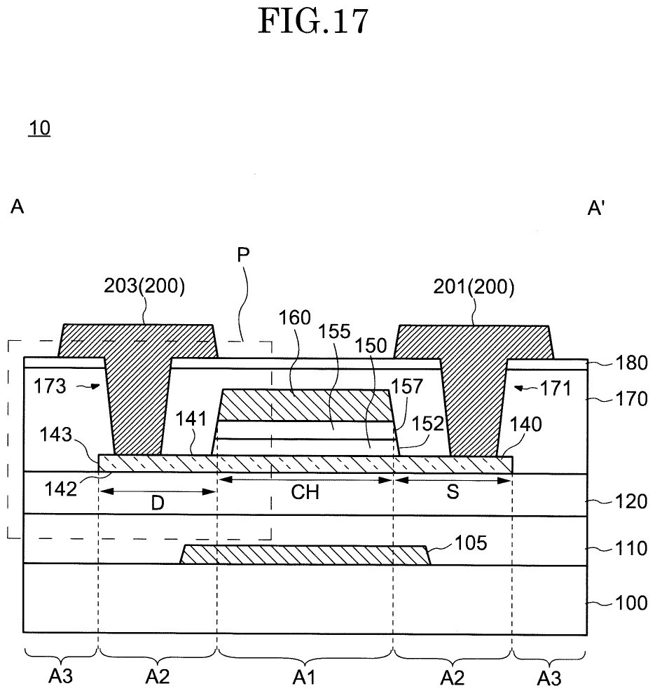

A semiconductor device according to an embodiment of the present invention will be described with reference to FIG. 17 to FIG. 22. The semiconductor device 10 according to the present embodiment is similar to the semiconductor device 10 according to the first embodiment, but is different in that the oxide insulating layer 150 is patterned in the same manner as the patterns of the gate electrode 160 and the nitride insulating layer 155. In the following description, a configuration common to the configuration of the semiconductor device 10 according to the first embodiment will be omitted, and a configuration that is mainly different from the configuration of the semiconductor device 10 according to the first embodiment will be described.

### [2-1. Configuration of Semiconductor Device 10]

A configuration of the semiconductor device 10 according to an embodiment of the present invention will be described with reference to FIG. 17. FIG. 17 is a cross-sectional view showing an outline of a semiconductor device according to an embodiment of the present invention. Since the planar shape of the semiconductor device 10 according to the present embodiment is the same as that of the semiconductor device 10 according to the first embodiment, the explanation will be omitted.

As shown in FIG. 17, the oxide insulating layer 150 is patterned. Similar to the nitride insulating layer 155, a pattern end of the oxide insulating layer 150 substantially matches the pattern end of the gate electrode 160. That is, in a plan view, the pattern of the oxide insulating layer 150 substantially matches the pattern of the gate electrode 160. In other words, a sidewall 152 of the oxide insulating layer 150 has a shape along the pattern of the gate electrode 160 in a plan view. In the second region A2 (the region that does not overlap the gate electrode 160 in a plan view), the oxide semiconductor layer 140 is in contact with the insulating layer 170. The sidewall 152 is in contact with the insulating layer 170 along with the sidewall 157. The sidewall 152 may be referred to as the “second sidewall.” In the present embodiment, an oxide insulating layer is used as the insulating layer 170, and a nitride insulating layer is used as the insulating layer 180.

### [2-2. Configuration of Hydrogen-Trapping Region]

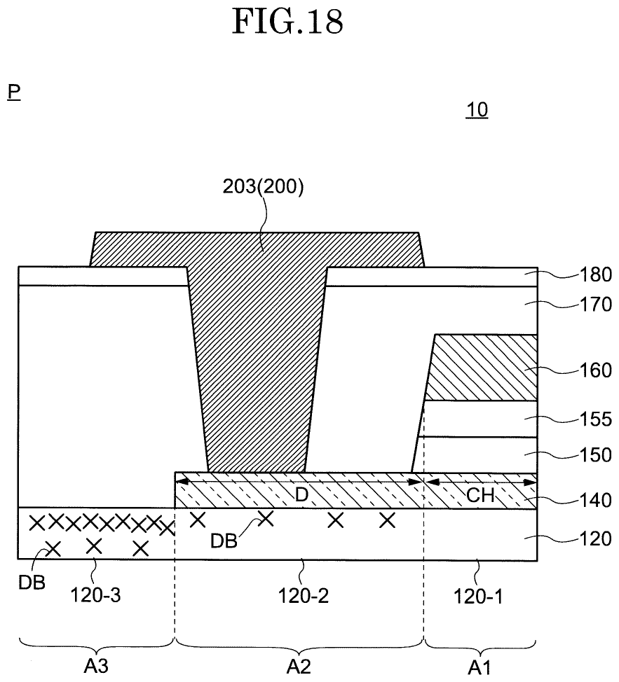

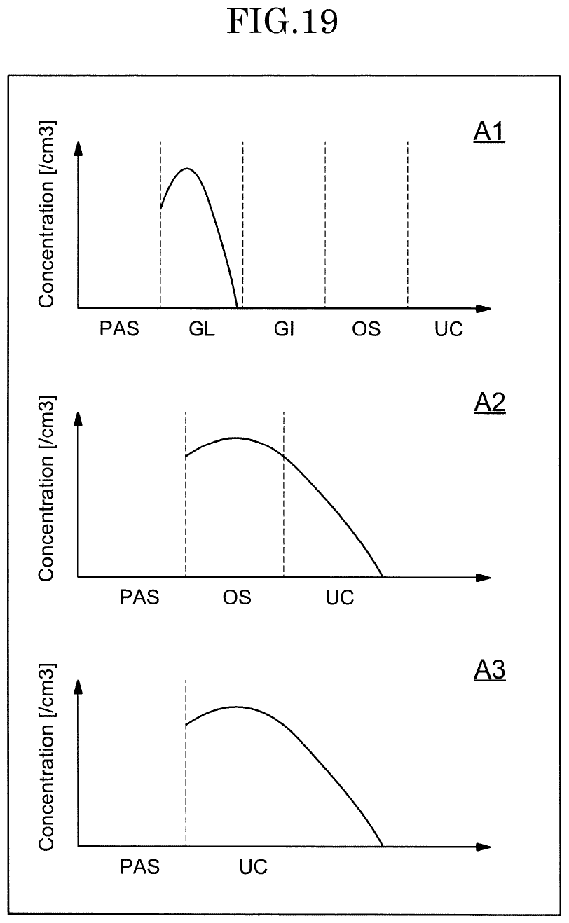

The hydrogen-trapping region is formed in the oxide insulating layer 120 in the semiconductor device 10 of the present embodiment. Therefore, a configuration of the hydrogen-trapping region formed in the oxide insulating layer 120 will be described with reference to FIG. 18 and FIG. 19. FIG. 18 is a schematic partially enlarged cross-sectional view showing a configuration of a semiconductor device according to an embodiment of the present invention. Specifically, FIG. 18 is an enlarged cross-sectional view of a region P in FIG. 17. Although the region P shown in FIG. 18 is a region in the vicinity of the drain region D, the vicinity of the source region S also has the same configuration as the region P.

The oxide insulating layer 120 is divided into the first region A1, the second region A2, and the third region A3. The oxide insulating layer 120 in each region is described as the oxide insulating layers 120-1, 120-2, and 120-3, respectively. The oxide insulating layers 120-1 and 120-2 are in contact with the oxide semiconductor layer 140. The oxide insulating layer 120-3 is in contact with the insulating layer 170.

Although details will be described later, in the semiconductor device 10 according to the present embodiment, the gate insulating layer (the oxide insulating layer 150 and the nitride insulating layer 155) is removed by etching in the second region A2 and the third region A3, and the ion implantation is performed with the oxide semiconductor layer 140 in the second region A2 and the oxide insulating layer 120 in the third region A3 exposed. In the second region A2, the implanted impurity ions reach the oxide insulating layer 120 via the oxide semiconductor layer 140. Similarly, in the third region A3, the implanted impurity ions are introduced into the exposed oxide insulating layer 120. Therefore, the dangling bond-defect DB is generated in the oxide insulating layer 120 in the second region A2 and the third region A3.

In the first region A1, impurities are ion-implanted using the gate electrode 160 as a mask. Therefore, in the first region A1, impurities are not implanted into the nitride insulating layer 155, the oxide insulating layer 150 and the oxide insulating layer 120-1, and the dangling bond-defect DB is not generated in these insulating layers. On the other hand, as described above, the dangling bond-defect DB is generated in the oxide insulating layers 120-2 and 120-3. For example, in the case where silicon oxide is used as the oxide insulating layer 120, the dangling bond-defect DB of silicon is formed in the oxide insulating layers 120-2 and 120-3.

The dangling bond-defect DB formed in the oxide insulating layer 120 traps hydrogen. That is, in the semiconductor device 10, the oxide insulating layers 120-2 and 120-3 function as a hydrogen-trapping region. Therefore, for example, hydrogen diffused from the insulating layer 170 at the time of deposition of the insulating layer 170 is trapped in the dangling bond-defect DB in the oxide insulating layers 120-2 and 120-3, so that it is possible to suppress hydrogen from entering the oxide semiconductor layer 140 in the channel region CH. Therefore, in the condition after the insulating layer 170 is deposited, the hydrogen concentrations of the oxide insulating layers 120-2 and 120-3 are higher than the hydrogen concentration of the oxide insulating layer 120-1.

Since the dangling bond-defect DB is formed by ion implantation, the oxide insulating layers 120-2 and 120-3 contain impurities introduced by ion implantation. The distribution of the amount of dangling bond-defect DB formed in the oxide insulating layers 120-2 and 120-3 corresponds to a concentration profile of the impurity contained therein. That is, the position and amount of the dangling bond-defect DB can be adjusted by adjusting the profile of the impurity obtained by the ion implantation.

FIG. 19 is a graph showing profiles of impurity concentrations in the first region A1 to the third region A3 in a semiconductor device according to the embodiment of the present invention. The vertical axes of each of the three concentration profiles shown in FIG. 19 indicate the concentration of impurities per unit volume (Concentration [/cm³]), and the horizontal axes indicate the name of the layer in a depth direction. The “UC” in the horizontal axis corresponds to the oxide insulating layer 120 and the nitride insulating layer 110. The “OS” corresponds to the oxide semiconductor layer 140. The “GI” corresponds to the oxide insulating layer 150 and the nitride insulating layer 155. The “GL” corresponds to the gate electrode 160. The “PAS” corresponds to the insulating layer 170.

As shown in FIG. 19, in the first region A1, the concentration profile of the impurity has a peak in the gate electrode 160 (GL). Therefore, in the depth direction in the first region A1, the amount of impurities contained in a predetermined position of the gate electrode 160 is greater than each of the amount of impurities contained in a predetermined position of the oxide insulating layer 150 and the nitride insulating layer 155 (GI), the amount of impurities contained in a predetermined position of the oxide semiconductor layer 140 (OS), and the amount of impurities contained in the oxide insulating layer 120 (UC). The above “depth direction” means a thickness direction of each layer. The metal material has a high stopping power against impurities introduced by ion implantation. If the metal material is used as the gate electrode 160, the impurities are blocked by the gate electrode 160 and do not reach the nitride insulating layer 155. Therefore, the dangling bond-defect DB due to the introduction of impurities is not formed in the nitride insulating layer 155, the oxide insulating layer 150 and the oxide insulating layer 120 in the first region A1. However, the impurities may reach the oxide insulating layer 150 and the nitride insulating layer 155 as long as the electrical characteristics of the semiconductor device 10 are not affected.

In the second region A2, the concentration profile of the impurity has peaks in the oxide semiconductor layer 140 (OS). Therefore, in the depth direction in the second region A2, the amount of impurities contained in the predetermined position of the oxide semiconductor layer 140 is greater than the amount of impurities contained in the predetermined position of the oxide insulating layer 120 (UC). Since the purpose of introducing impurities is to reduce the resistance of the oxide semiconductor layer 140 in the source region S and the drain region D, the ion implantation condition is set so as to have the above-described concentration profile. The amount of impurities contained in the oxide semiconductor layer 140 in the second region A2 is greater than the amount of impurities contained in the oxide semiconductor layer 140 in the first region A1. Similarly, the amount of impurities contained in the oxide insulating layer 120 (UC) in the second region A2 is greater than the amount of impurities contained in the oxide insulating layer 120 in the first region A1.

As described above, in the second region A2, impurities are also introduced into the oxide insulating layer 120. Therefore, the dangling bond-defect DB associated with the introduction of impurities is formed in the oxide insulating layer 120-2 (see FIG. 18).

In the third region A3, the concentration profile of the impurity has a peak in the oxide insulating layer 120 (UC). In the third region A3, the oxide semiconductor layer 140 is not arranged on the oxide insulating layer 120. As a result, instead of having the peak of the concentration profile in the oxide semiconductor layer 140 in the second region A2, there is the peak of the concentration profile in the oxide insulating layer 120 in the third region A3. That is, the amount of impurities contained in the oxide insulating layer 120 in the third region A3 is greater than the amount of impurities contained in the oxide insulating layer 120 in the first region A1 and greater than the amount of impurities contained in the oxide insulating layer 120 in the second region A2.

According to the concentration profile of the impurity as described above, the dangling bond-defect DB associated with the introduction of the impurity is formed in the oxide insulating layer 120-3 (see FIG. 18). As described above, since the peak of the concentration profile is present in the oxide insulating layer 120 in the third region A3, the amount of dangling bond-defect DB present in the oxide insulating layer 120 in the third region A3 is greater than the amount of dangling bond-defect DB present in the oxide insulating layer 120 in the second region A2. Therefore, the oxide insulating layer 120 in the third region A3 can trap more hydrogen than the oxide insulating layer 120 in the second region A2.

In the present embodiment, in the depth direction of the third region A3, the amount of impurities contained at a predetermined position in the oxide insulating layer 120 is 1×10¹⁶/cm³ or more, 1×10¹⁷/cm³ or more, or 1×10¹⁸/cm³ or more. The predetermined position may be a peak position of the concentration profile or a position corresponding to an interface between the oxide insulating layer 120 and the insulating layer 170. Alternatively, the predetermined position may be a position moved by a predetermined depth from a position corresponding to the interface toward the oxide insulating layer 120.

In the present embodiment, although a configuration in which the amount of impurities contained in the oxide insulating layer 120 in the third region A3 is greater than the amount of impurities contained in the oxide insulating layer 120 in the second region A2 is exemplified, the configuration is not limited to this configuration. Similarly, in the present embodiment, although a configuration in which the peak of the concentration profile of the impurity in the third region A3 is present in the oxide insulating layer 120 is exemplified, the configuration is not limited to this configuration. For example, in the depth direction of the third region A3, the concentration of impurities at the top surface of the oxide insulating layer 120 (the surface corresponding to the interface between the oxide insulating layer 120 and the insulating layer 170) may be the highest.

### [2-3. Method for Manufacturing Semiconductor Device 10]

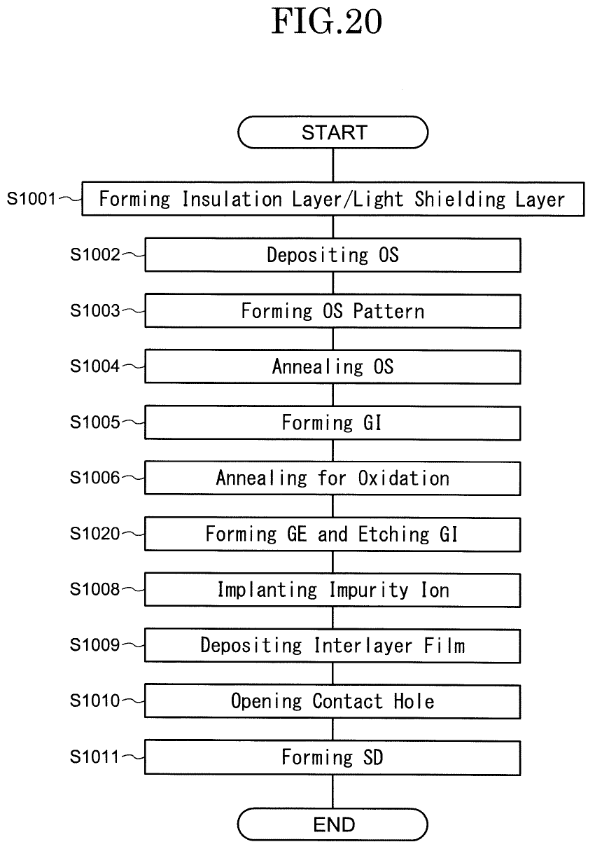

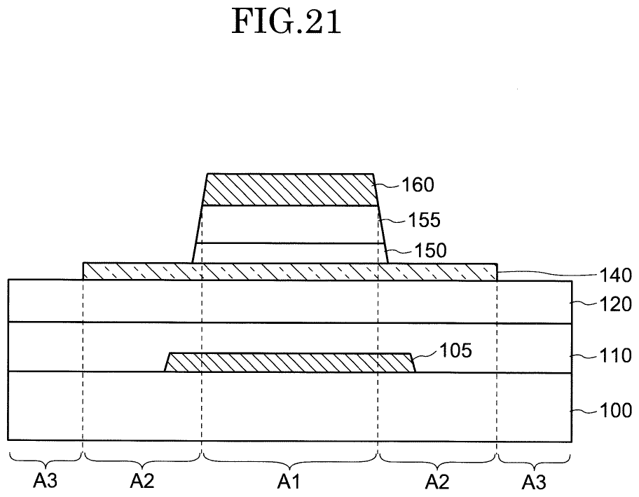

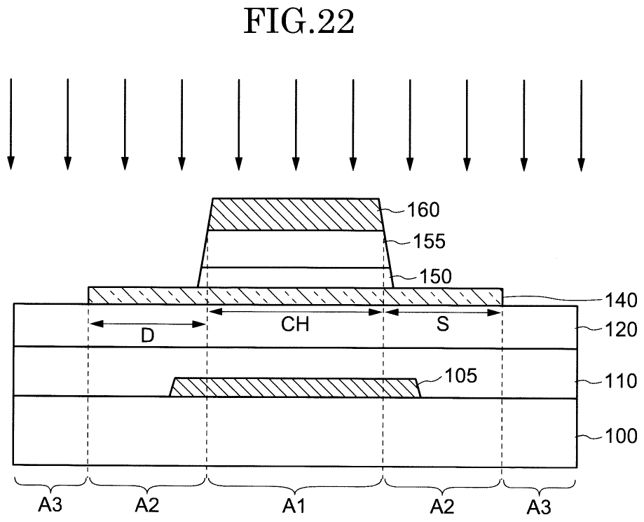

A method for manufacturing a semiconductor device 10 according to an embodiment of the present invention will be described with reference to FIG. 20 to FIG. 22. FIG. 20 is a sequence diagram showing a method for manufacturing a semiconductor device according to an embodiment of the present invention. FIG. 21 and FIG. 22 are cross-sectional views showing a method for manufacturing a semiconductor device according to an embodiment of the present invention.

A sequence of the semiconductor device 10 according to the present embodiment is similar to a sequence of the semiconductor device 10 according to the first embodiment (FIG. 5), but they are different in that instead of GI half-etching of S1007 in FIG. 5, GI etching is performed in S1020 in FIG. 20. In the following description, since the steps of S1001 to S1006 are the same as those in FIG. 5, the explanation will be omitted.

As shown in FIG. 20 and FIG. 21, the gate electrode 160 is deposited, and the gate electrode 160, the nitride insulating layer 155, and the oxide insulating layer 150 are simultaneously etched (“Forming GE and Etching GI” in step S1020 of FIG. 5). The gate electrode 160 is deposited by the sputtering method or the atomic-layer deposition method. The gate electrode 160, the nitride insulating layer 155, and the oxide insulating layer 150 are patterned by the photolithography process. The gate electrode 160, the nitride insulating layer 155, and the oxide insulating layer 150 may be etched in the same process (the same conditions), and each may be etched in a different process (different conditions). That is, the etching of the nitride insulating layer 155 and the oxide insulating layer 150 may be performed by over-etching in the etching process for the gate electrode 160, and may be performed by an etching different from the etching for the gate electrode 160 using the gate electrode 160 as a mask after the etching of the gate electrode 160.

As shown in FIG. 22, the gate electrode 160, the nitride insulating layer 155, and the oxide insulating layer 150 are patterned to expose the oxide semiconductor layer 140 in the second region A2 and to expose the oxide insulating layer 120 in the third region A3. In this state, impurity ions are implanted into the exposed oxide insulating layer 120 and the oxide semiconductor layer 140 (“Implanting Impurity lon” in step S1008 of FIG. 20). Specifically, impurities are implanted into the exposed oxide insulating layer 120 and the oxide semiconductor layer 140 using the gate electrode 160 as a mask.

Through the above steps, the channel region CH is formed in the oxide semiconductor layer 140 in the first region A1, and the source region S and the drain region D are formed in the oxide semiconductor layer 140 in the second region A2.

The dangling bond-defect DB is generated in the oxide insulating layer 120 in the second region A2 and the third region A3 by the ion implantation. The position and amount of the dangling bond-defect DB can be controlled by adjusting the process parameters (for example, dose amount, acceleration voltage, plasma power, and the like) of the ion implantation. For example, the dose amount is 1×10¹⁴/cm² or more, 5×10¹⁴/cm² or more, or 1×10¹⁵/cm² or more. For example, the acceleration voltage is 10 keV or more, 15 keV or more, or 20 keV or more.

In the semiconductor device 10 according to the present embodiment, since many dangling bond defects DB are formed in the oxide insulating layer 120 in the third region A3 surrounding the channel region CH, it is possible to obtain the same effect similar to the semiconductor device 10 according to the first embodiment.

### 3. Third Embodiment

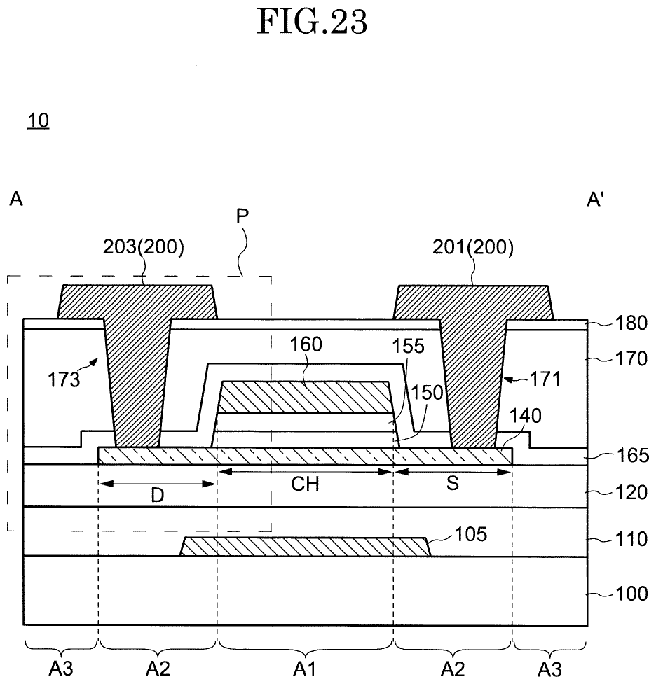

The semiconductor device according to an embodiment of the present invention will be described with reference to FIG. 23 to FIG. 28. The semiconductor device 10 according to the present embodiment is similar to the semiconductor device 10 according to the second embodiment, but is different in that an oxide insulating layer 165 is arranged between the gate electrode 160 and the insulating layer 170. In the following description, a configuration common to the semiconductor device 10 according to the second embodiment will be omitted, and a configuration that is mainly different from the configuration of the semiconductor device 10 according to the second embodiment will be described.

### [3-1. Configuration of Semiconductor Device 10]

The configuration of the semiconductor device 10 according to an embodiment of the present invention will be described. FIG. 23 is a cross-sectional view showing an outline of a semiconductor device according to an embodiment of the present invention. Since the plan view of the semiconductor device 10 is the same as the plan view shown in FIG. 2, the explanation will be omitted.

As shown in FIG. 23, the semiconductor device 10 includes the oxide insulating layer 165 in addition to the light-shielding layer 105, the nitride insulating layer 110, the oxide insulating layer 120, the oxide semiconductor layer 140, the oxide insulating layer 150, the nitride insulating layer 155, the gate electrode 160, the insulating layers 170 and 180, and the source/drain electrode 200. As described above, a nitride insulating layer is used as the insulating layer 170.

The oxide insulating layer 165 covers the oxide semiconductor layer 140 and the gate electrode 160. That is, the oxide insulating layer 165 is arranged between the gate electrode 160 and the insulating layer 170 in the first region A1, between the oxide semiconductor layer 140 and the insulating layer 170 in the second region A2, and between the oxide insulating layer 120 and the insulating layer 170 in the third region A3. A thickness of the oxide insulating layer 165 is 50 nm or more and 100 nm or less, or 70 nm or more and 100 nm or less.

### [3-2. Configuration of Hydrogen-Trapping Region]

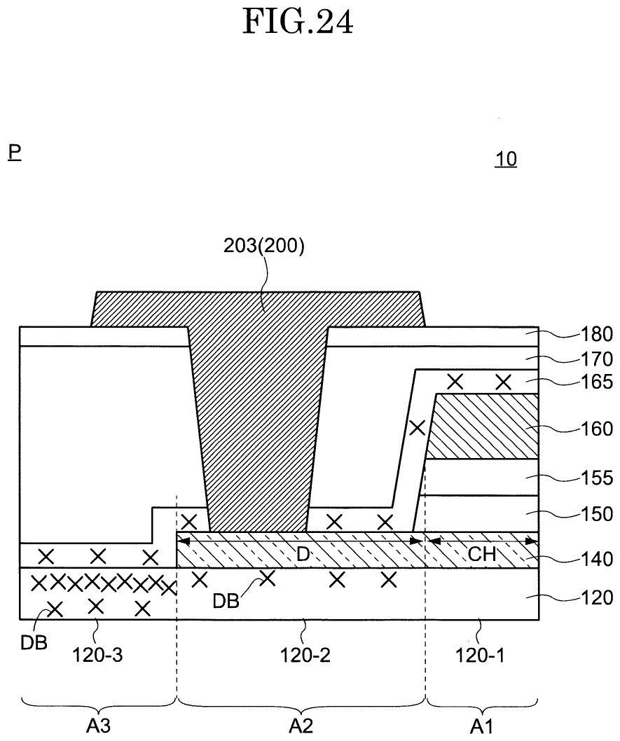

FIG. 24 is a schematic partially enlarged cross-sectional view showing a configuration of a semiconductor device according to an embodiment of the present invention. Although details will be described later, the dangling bond-defect DB formed in the oxide insulating layer 120 and the oxide insulating layer 165 shown in FIG. 24 is generated by one ion implantation after forming the oxide insulating layer 165.

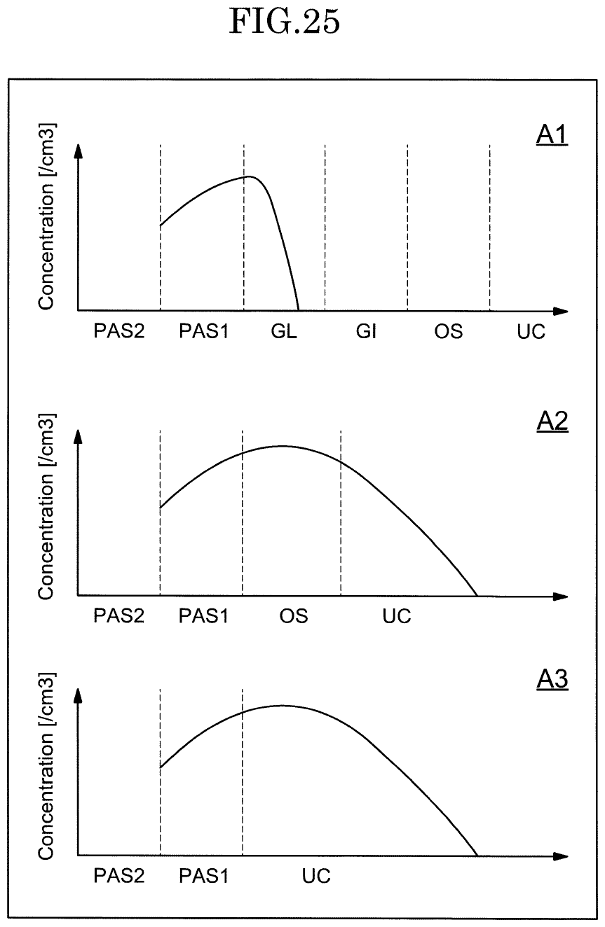

FIG. 25 is a graph showing the profile of the impurity concentration in the first region A1 to the third region A3 in a semiconductor device according to the embodiment of the present invention. The vertical axis of each of the three concentration profiles shown in FIG. 25 indicates the concentration of impurities per unit volume (Concentration [/cm³]), and the horizontal axis indicates the name of the layer in the depth direction. The “UC” in the horizontal axis corresponds to the oxide insulating layer 120 and the nitride insulating layer 110. The “OS” corresponds to an oxide semiconductor layer 140. The “GI” corresponds to the oxide insulating layer 150 and the nitride insulating layer 155. The “GL” corresponds to the gate electrode 160. The “PAS1” corresponds to the oxide insulating layer 165. The “PAS2” corresponds to the insulating layer 170.

As shown in FIG. 25, in the first region A1, impurities are contained in the gate electrode 160 (GL) and the oxide insulating layer 165 (PAS1), and the concentration profile of the impurities has a peak in the gate electrode 160. Therefore, in the depth direction in the first region A1, the amount of impurities contained in the predetermined positions of each of the gate electrode 160 and the oxide insulating layer 165 is greater than each of the amount of impurities contained in the predetermined position of the oxide insulating layer 150 and the nitride insulating layer 155 (GI), the amount of impurities contained in the predetermined position of the oxide semiconductor layer 140 (OS), and the amount of impurities contained in the oxide insulating layer 120 (UC).

In the second region A2, impurities are contained in the oxide insulating layer 120 (UC), the oxide semiconductor layer 140 (OS), and the oxide insulating layer 165 (PAS1), and the concentration profile of the impurities has a peak in the oxide semiconductor layer 140. Therefore, in the depth direction in the second region A2, the amount of impurities contained in the predetermined position of the oxide semiconductor layer 140 is greater than the amount of impurities contained in the predetermined position of the oxide insulating layer 120 and greater than the amount of impurities contained in the predetermined position of the oxide insulating layer 165.

As described above, in the second region A2, impurities are introduced into the oxide insulating layer 120 and the oxide insulating layer 165. Therefore, the dangling bond-defect DB associated with the introduction of impurities is formed in the oxide insulating layer 120 and the oxide insulating layer 165.

In the third region A3, impurities are contained in the oxide insulating layer 120 and the insulating layer 165, and the concentration profile of the impurities has a peak in the oxide insulating layer 120 (UC). In the third region A3, the oxide semiconductor layer 140 is not arranged on the oxide insulating layer 120. As a result, instead of having the peak of the concentration profile in the oxide semiconductor layer 140 in the second region A2, there is the peak of the concentration profile in the oxide insulating layer 120 in the third region A3. That is, the amount of impurities contained in the oxide insulating layer 120 in the third region A3 is greater than the amount of impurities contained in the oxide insulating layer 120 in the first region A1 and greater than the amount of impurities contained in the oxide insulating layer 120 in the second region A2.

According to the concentration profile of the impurity as described above, the dangling bond-defect DB associated with the introduction of impurities is formed in the oxide insulating layer 120 and the oxide insulating layer 165. As described above, in the third region A3, since the peak of the concentration profile is present in the oxide insulating layer 120, the amount of dangling bond-defect DB present in the oxide insulating layer 120 in the third region A3 is greater than the amount of the dangling bond defect DB present in the oxide insulating layer 120 in the second region A2. Therefore, the oxide insulating layer 120 in the third region A3 can trap more hydrogen than the oxide insulating layer 120 in the second region A2. Since the thickness of the oxide insulating layer 165 is 50 nm or more, a remarkable effect is obtained by trapping hydrogen from the insulating layer 170.

In the present embodiment, as described above, although a configuration in which the concentration profile of the impurity has a peak in the gate electrode 160 in the first region A1, the concentration profile has a peak in the oxide semiconductor layer 140 in the second region A2, and the concentration profile has a peak in the oxide insulating layer 120 in the third region A3 has been exemplified, the configuration is not limited to this configuration.

For example, if the thickness of the oxide semiconductor layer 140 is relatively thin, the concentration profile in the second region A2 may have a peak in the oxide insulating layer 120 or near the interface between the oxide semiconductor layer 140 and the oxide insulating layer 120. On the other hand, if the thickness of the oxide insulating layer 165 is relatively thick, the concentration profile may have a peak in the oxide insulating layer 165 or near the interface between the oxide insulating layer 165 and the lower layer of the oxide insulating layer 165 in the first region A1 to the third region A3. The lower layer of the oxide insulating layer 165 is the gate electrode 160 in the first region A1, the oxide semiconductor layer 140 in the second region A2, and the oxide insulating layer 120 in the third region A3.

In the present embodiment, in the depth direction of the third region A3, the amount of impurities contained in a predetermined position in the oxide insulating layer 120 is 1×10¹⁶/cm³ or more, 1×10¹⁷/cm³ or more, or 1×10¹⁸/cm³ or more. The predetermined position may be the peak position of the concentration profile or a position corresponding to an interface between the oxide insulating layer 120 and the oxide insulating layer 165. Alternatively, the predetermined position may be a position moved by a predetermined depth from a position corresponding to the interface toward the oxide insulating layer 120.

### [3-3. Method for Manufacturing Semiconductor Device 10]

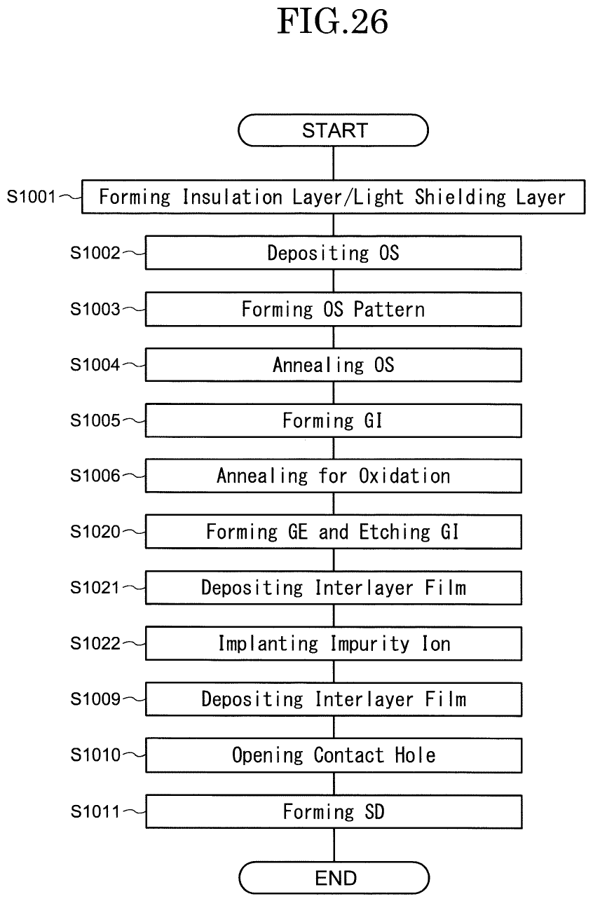

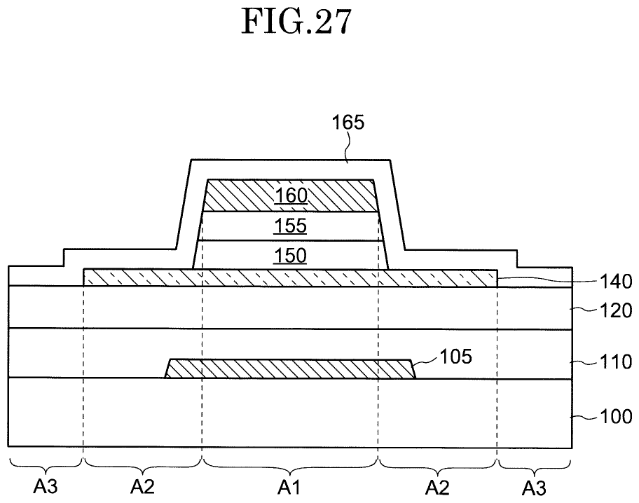

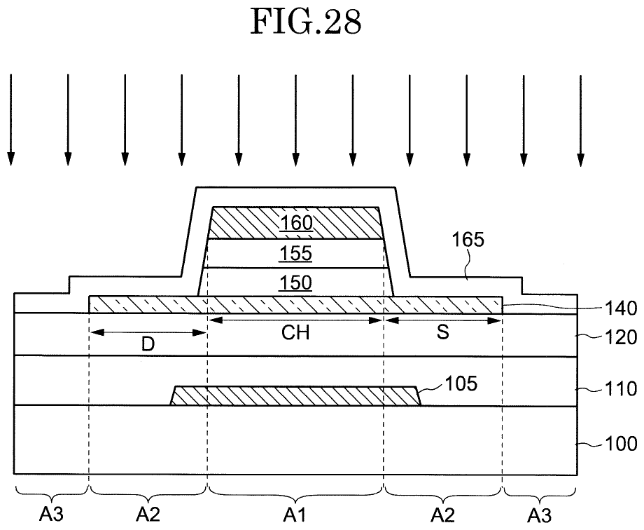

A method for manufacturing the semiconductor device 10 according to an embodiment of the present invention will be described with reference to FIG. 26 to FIG. 28. FIG. 26 is a sequence diagram showing a method for manufacturing a semiconductor device according to an embodiment of the present invention. FIG. 27 to FIG. 28 are cross-sectional views showing a method for manufacturing a semiconductor device according to an embodiment of the present invention. Since the steps S1001 to S1006 and S1020 shown in FIG. 26 are the same as the steps S1001 to S1006 and S1020 shown in FIG. 20, descriptions thereof will be omitted.

Similar to FIG. 21, the gate electrode 160 is deposited and the gate electrode 160, the oxide insulating layer 150 and the nitride insulating layer 155 are etched at once, and then, as shown in FIG. 27, the oxide insulating layer 165 is deposited on the oxide insulating layer 120, the oxide semiconductor layer 140, and the gate electrode 160 (“oxide insulating layer forming” in step S1021 of FIG. 26). The oxide insulating layer 165 is formed by the CVD method. For example, a silicon oxide layer is formed as the oxide insulating layer 165. An insulating layer having a relatively low hydrogen content is used as the oxide insulating layer 165. For example, the hydrogen content of the oxide insulating layer 165 is 1×10²¹ cm⁻³ or less.

In the case where a silicon oxide layer is used as the oxide insulating layer 165, the silicon oxide layer is deposited under a condition where the ratio of silane (SiH₄) to dinitrogen oxide (N₂O) is relatively small. For example, in these conditions, [N₂O/SiH₄] is 30 or less.

In the case where the impurity is allowed to reach the oxide insulating layer 120 by ion implantation, there is a limitation due to the acceleration voltage of the ion implantation device. Therefore, the thickness of the oxide insulating layer 165 is less than 100 nm.

As shown in FIG. 26 and FIG. 28, impurities are ion-implanted into the oxide insulating layer 165 (“Implanting Impurity Ion” in step S1022 of FIG. 26). In the present embodiment, impurities are implanted so that the peak of the concentration profile of the impurity is present in the oxide semiconductor layer 140 (second region A2) and the oxide insulating layer 120 (third region A3) arranged below the oxide insulating layer 165. For example, elements such as boron (B), phosphorus (P), argon (Ar), or nitrogen (N) are implanted into the oxide semiconductor layer 140 and the oxide insulating layer 120 via the oxide insulating layer 165 by ion implantation. The dangling bond-defect DB is generated in the oxide insulating layer 120 in the second region A2, the oxide insulating layer 120 in the third region A3, and the oxide insulating layer 165 in the first to third region A1 by the ion implantation. The position and amount of the dangling bond-defect DB can be controlled by adjusting the process parameters (for example, dose amount, acceleration voltage, plasma power, and the like) of the ion implantation. For example, the dose amount is 1×10¹⁴/cm² or more, 5×10¹⁴/cm² or more, or 1×10¹⁵/cm² or more. For example, in the case where the element to be implanted is boron (B), the acceleration voltage is 10 keV or more and 50 keV or less.

After the above ion implantation, the insulating layers 170 and 180 are deposited on the oxide insulating layer 165 as interlayer films (“Depositing Interlayer Film” in step S1009 of FIG. 26), and openings 171 and 173 are formed in the insulating layers 170 and 180 (“Opening Contact Hole” in step S1010 of FIG. 26). Forming a source/drain electrode 200 on the oxide semiconductor layer 140 and insulating layer 180 exposed by the openings 171 and 173 (“Forming SD” in step S1011 of FIG. 26) completes the semiconductor device 10 similar to that of FIG. 23.

In the present embodiment, as shown in FIG. 24 and FIG. 25, the dangling bond-defect DB is formed in the oxide insulating layer 165 in addition to the oxide insulating layer 120, so that it is possible to suppress hydrogen from entering the oxide semiconductor layer 140 in the channel region CH. As a result, it is possible to obtain the semiconductor device 10 having electrical characteristics in which humps are suppressed. Further, in the present embodiment, since the insulating layer having relatively low hydrogen content is used as the oxide insulating layer 165, at the time of deposition of the oxide insulating layer 165, it is possible to suppress hydrogen from entering the oxide semiconductor layer 140 in the channel region CH. In addition, the dangling bond-defect DB can be formed in both the oxide insulating layer 120 and the oxide insulating layer 165 by one ion implantation.

### 4. Fourth Embodiment

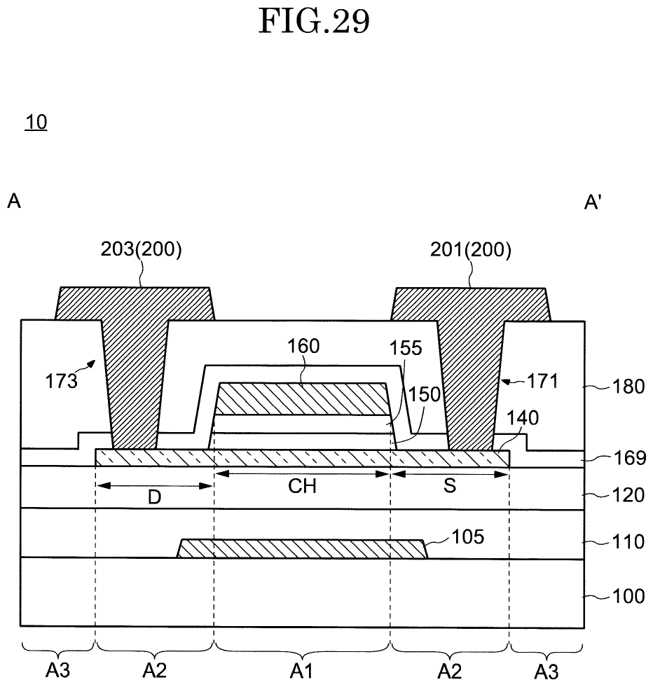

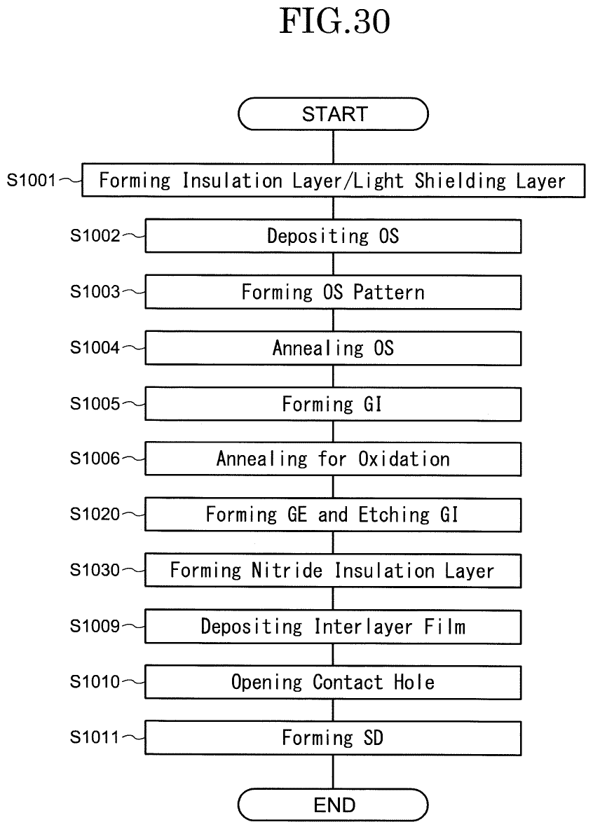

A semiconductor device according to an embodiment of the present invention will be described with reference to FIG. 29 and FIG. 30. The semiconductor device 10 according to the present embodiment is similar to the semiconductor device 10 according to the third embodiment, but is different in that a nitride insulating layer 169 is arranged instead of the oxide insulating layer 165. In the following description, a configuration common to the configuration of the semiconductor device 10 according to the third embodiment will be omitted, and a configuration that is mainly different from the configuration of the semiconductor device 10 according to the third embodiment will be described.

### [4-1. Configuration of Semiconductor Device 10]

FIG. 29 is a cross-sectional view showing an outline of a semiconductor device according to an embodiment of the present invention. Since the plan view of the semiconductor device 10 is the same as the plan view shown in FIG. 2, the explanation will be omitted. As shown in FIG. 29, in the semiconductor device 10 according to the present embodiment, the nitride insulating layer 169 is arranged on the gate electrode 160, and the insulating layer 180 is arranged on the nitride insulating layer 169. An oxide insulating layer is used as the insulating layer 180 as described above.

The nitride insulating layer 169 covers the oxide semiconductor layer 140 and the gate electrode 160. That is, the nitride insulating layer 169 is arranged between the gate electrode 160 and the insulating layer 180 in the first region A1, between the oxide semiconductor layer 140 and the insulating layer 180 in the second region A2, and between the oxide insulating layer 120 and the insulating layer 180 in the third region A3. In the second region A2 (the region that does not overlap the gate electrode 160 in a plan view), the nitride insulating layer 169 is in contact with the oxide semiconductor layer 140. A thickness of the nitride insulating layer 169 is 50 nm or more and 300 nm or less, or 70 nm or more and 100 nm or less.

### [4-2. Method for Manufacturing Semiconductor Device 10]

A method for manufacturing the semiconductor device 10 according to an embodiment of the present invention will be described with reference to FIG. 30. FIG. 30 is a sequence diagram showing a method for manufacturing a semiconductor device according to an embodiment of the present invention. Since steps S1001 to S1006 and S1020 shown in FIG. 30 are similar to steps S1001 to S1006 and S1020 shown in FIG. 26, the explanation will be omitted.

Similar to FIG. 21, the gate electrode 160 is deposited, and the gate electrode 160, the nitride insulating layer 155, and the oxide insulating layer 150 are simultaneously etched, and then the nitride insulating layer 169 is deposited on the oxide insulating layer 120, the oxide semiconductor layer 140, and the gate electrode 160 similar to FIG. 27 (“Nitride insulating layer formation” in step S1030 of FIG. 30). The nitride insulating layer 169 is deposited by the CVD method. For example, a silicon nitride layer is formed as the nitride insulating layer 169.

When the nitride insulating layer 169 is deposited on the oxide semiconductor layer 140 with the oxide semiconductor layer 140 exposed, an oxygen vacancy is generated in the oxide semiconductor layer 140 in the region (the source region S and the drain region D) on which the nitride insulating layer 169 is deposited. Hydrogen is trapped in the generated oxygen defect, so that the resistance of the oxide semiconductor layer 140 in the source region S and the drain region D is reduced due to hydrogen-trapping in the generated oxygen-deficiencies. That is, in the method for manufacturing the semiconductor device 10 according to the present embodiment, the resistance of the oxide semiconductor layer 140 can be reduced without implanting impurity ions into the oxide semiconductor layer 140. Since the steps of S1009 to S1011 of FIG. 30 are the same as the steps of S1009 to S1011 of FIG. 26, the explanation will be omitted.

In the present embodiment, as described above, the resistance of the oxide semiconductor layer 140 in the source region S and the drain region D can be reduced without implanting impurity ions into the oxide semiconductor layer 140.

### 5. Fifth Embodiment

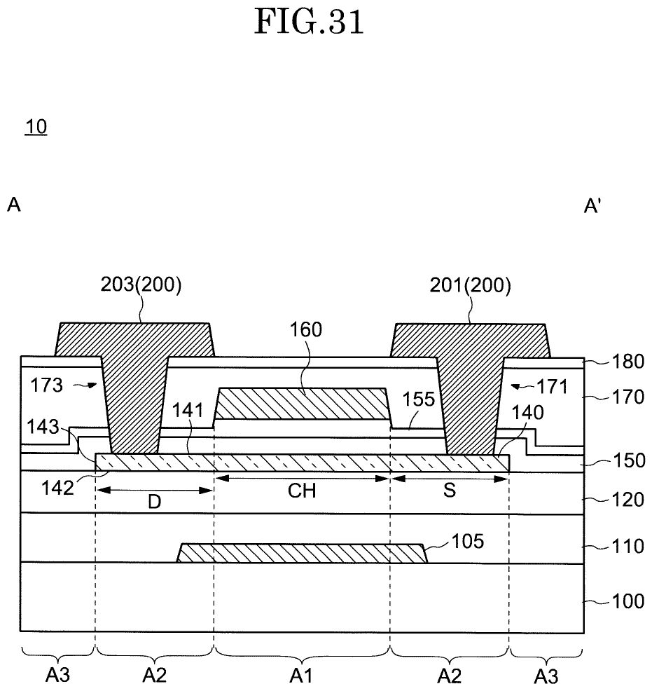

A semiconductor device according to an embodiment of the present invention will be described with reference to FIG. 31 to FIG. 33. The semiconductor device 10 according to the present embodiment is similar to the semiconductor device 10 according to the first embodiment, but is different in that the nitride insulating layer 155 is formed on the oxide insulating layer 150 in the second region A2 and the third region A3. In the following description, a configuration common to the configuration of the semiconductor device 10 according to the first embodiment will be omitted, and a configuration that is mainly different from the configuration of the semiconductor device 10 according to the first embodiment will be described.

### [5-1. Configuration of Semiconductor Device 10]

FIG. 31 is a cross-sectional view showing an outline of a semiconductor device according to an embodiment of the present invention. Since the plan view of the semiconductor device 10 is the same as the plan view shown in FIG. 2, the explanation will be omitted. As shown in FIG. 31, in the semiconductor device 10 according to the present embodiment, the nitride insulating layer 155 is half-etched using the gate electrode 160 as a mask. That is, a thickness of the nitride insulating layer 155 in the second region A2 and the third region A3 (the region that does not overlap the gate electrode 160 in a plan view) is smaller than the thickness of the nitride insulating layer 155 in the first region A1 (the region that overlaps the gate electrode 160 in a plan view).

The total thickness of the oxide insulating layer 150 and the nitride insulating layer 155 in the first region A1 is 200 nm or more. The total thickness of the oxide insulating layer 150 and the nitride insulating layer 155 in the second region A2 and the third region A3 is 100 nm or less. Although the configuration in which the nitride insulating layer 155 remains uniform in the second region A2 and the third region A3 is exemplified in FIG. 31, the configuration is not limited to this configuration. For example, the nitride insulating layer 155 may not remain in part of the regions of the second region A2 and the third region A3. That is, the nitride insulating layer 155 may be completely etched in the part of the regions.

### [5-2. Method for Manufacturing Semiconductor Device 10]

Since the sequence diagram showing a method for manufacturing the semiconductor device 10 according to the present embodiment is the same as that shown in FIG. 5, the explanation will be omitted. In the first embodiment, the nitride insulating layer 155 is completely etched in GI half-etching of S1007 in FIG. 5, whereas in the present embodiment, the nitride insulating layer 155 is etched so as to leave a portion of it in the GI half-etching.

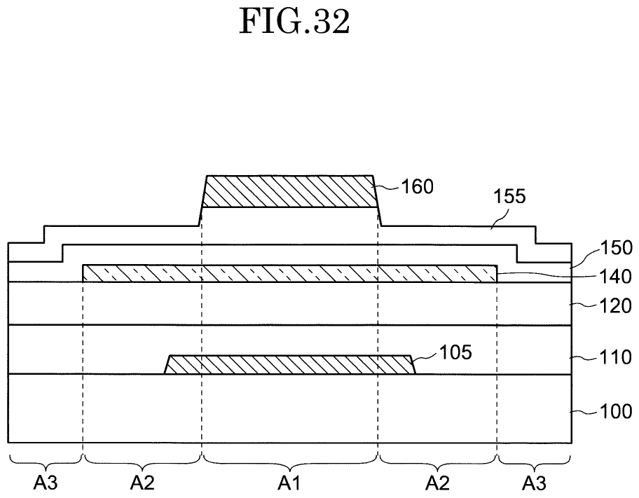

As shown in FIG. 32, the gate electrode 160 is formed and the nitride insulating layer 155 is half-etched using the gate electrode 160 as a mask. The half-etching of the nitride insulating layer 155 is performed by measuring the etching rate of the nitride insulating layer 155 according to the etching condition used for the half-etching in advance, and setting the etching time based on the etching rate. By the half-etching, the total thickness of the nitride insulating layer 155 and the oxide insulating layer 150 in the second region A2 and the third region A3 is thinned to 100 nm or less. The total thickness of the nitride insulating layer 155 and the oxide insulating layer 150 in the second region A2 and the third region A3 after the half-etching may be 50 nm or less or 30 nm or less.

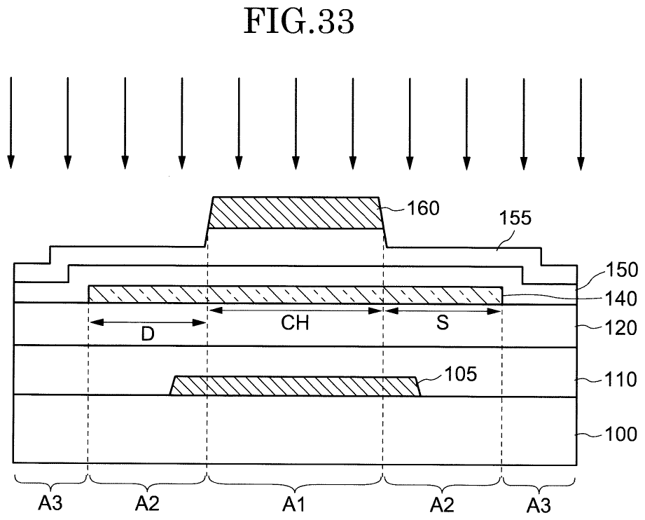

As shown in FIG. 33, impurity ions are implanted into the oxide semiconductor layer 140 with the nitride insulating layer 155 half-etched. Specifically, an impurity is implanted into the oxide insulating layer 120, the oxide semiconductor layer 140, the oxide insulating layer 150, and the nitride insulating layer 155 using the gate electrode 160 as a mask. For example, elements such as boron (B), phosphorus (P), argon (Ar), or nitrogen (N) are implanted into the oxide insulating layer 120, the oxide semiconductor layer 140, and the oxide insulating layer 150 by ion implantation. After that, the semiconductor device 10 is completed by performing the same process as the steps of S1009 to S1011 in FIG. 5.

In the semiconductor device 10 according to the present embodiment, the same effect as that of the semiconductor device 10 according to the first embodiment can be obtained.

Each of the embodiments described above as an embodiment of the present invention can be appropriately combined and implemented as long as no contradiction is caused. Furthermore, the addition, deletion, or design change of components, or the addition, deletion, or condition change of process as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first oxide insulating layer;
an oxide semiconductor layer above the first oxide insulating layer;
a second oxide insulating layer covering the oxide semiconductor layer;
a nitride insulating layer above the second oxide insulating layer;
a gate electrode above the nitride insulating layer; and
an insulating layer covering the gate electrode,
wherein
the nitride insulating layer has a first sidewall having a shape matching a pattern of the gate electrode in a plan view, and
the first sidewall is in contact with the insulating layer.

2. The semiconductor device according to claim 1, wherein the second oxide insulating layer is in contact with the insulating layer in a region not overlapping the gate electrode in the plan view.

3. The semiconductor device according to claim 1, wherein a thickness of the nitride insulating layer in a region not overlapping the gate electrode in the plan view is smaller than a thickness of the nitride insulating layer in a region overlapping the gate electrode in the plan view.

4. The semiconductor device according to claim 1, wherein
a thickness of the second oxide insulating layer in a region not overlapping the gate electrode in the plan view is 100 nm or less, and
a total thickness of the second oxide insulating layer and the nitride insulating layer in a region overlapping the gate electrode in the plan view is 200 nm or more.

5. The semiconductor device according to claim 1, wherein an amount of impurities contained in the oxide semiconductor layer in a second region not overlapping the gate electrode in the plan view is greater than an amount of the impurities contained in the oxide semiconductor layer in a first region overlapping the gate electrode in the plan view.

6. The semiconductor device according to claim 1, wherein
the second oxide insulating layer has a second sidewall having a shape matching a pattern of the gate electrode in a plan view, and
the second sidewall is in contact with the insulating layer.

7. The semiconductor device according to claim 1, wherein the oxide semiconductor layer is in contact with the insulating layer in a region not overlapping the gate electrode in the plan view.

8. The semiconductor device according to claim 7, wherein the insulating layer is an oxide insulating layer.

9. The semiconductor device according to claim 7, wherein the insulating layer is a nitride insulating layer.

10. The semiconductor device according to claim 6, wherein
a thickness of the insulating layer in a region not overlapping the gate electrode in the plan view is 100 nm or less, and
a total thickness of the second oxide insulating layer and the nitride insulating layer in a region overlapping the gate electrode in the plan view is 200 nm or more.

11. The semiconductor device according to claim 6, wherein an amount of impurities contained in the oxide semiconductor layer in a second region not overlapping the gate electrode in the plan view is greater than an amount of the impurities contained in the oxide semiconductor layer in a first region overlapping the gate electrode in the plan view.

12. The semiconductor device according to claim 11, wherein an amount of the impurities contained in the first oxide insulating layer in the second region is greater than an amount of the impurities contained in the first oxide insulating layer in the first region.

13. The semiconductor device according to claim 12, wherein an amount of the impurities contained in the first oxide insulating layer in a third region not overlapping the oxide semiconductor layer in a plan view is greater than an amount of the impurities contained in the first oxide insulating layer in the second region.
